(19) United States
(12) Patent Application Publication
(10) Pub. No.: US 2024/0158578 A1
(43) Pub. Date: May 16, 2024

(54) POLYIMIDE PRECURSOR COMPOSITION AND POLYIMIDE FILM

(71) Applicant: UBE Corporation, Ube-Shi (JP)

(72) Inventors: Takuya OKA, Ube-shi (JP); Yuki NEMOTO, Ube-shi (JP); Yukinori KOHAMA, Ube-shi (JP); Taichi ITO, Ube-shi (JP)

(21) Appl. No.: 18/546,390

(22) PCT Filed: Feb. 17, 2022
(86) PCT No.: PCT/JP2022/006442

§ 371 Date: Aug. 14, 2023

(30) Foreign Application Priority Data
Feb. 19, 2021 (JP) 2021-025747
Mar. 12, 2021 (JP) 2021-039787
Jul. 2, 2021 (JP) 2021-110718

(51) Int. Cl. C08G 73/10; C08J 5/18; C08K 5/3447; C08L 79/08

(52) U.S. Cl. CPC C08G 73/1078; C08G 73/1032; C08G 73/105; C08J 5/18; C08K 5/3447; C08L 79/08; C08J 2479/08; C08L 2201/10; C08L 2203/16; C08L 2203/20

(57) ABSTRACT

A precursor composition which can produce a polyimide film with excellent light transmittance, mechanical properties, coefficient of linear thermal expansion and resistance to thermal decomposition; and a polyimide film obtained from the precursor composition. The polyimide precursor composition contains a polyimide precursor with a repeating unit represented by formula (I); an imidazole compound in an amount more than 0.01 mol and 2 mol or less based on one mol of the repeating units of the polyimide precursor, and a solvent.

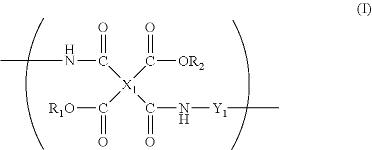

In general formula I, 70 mol. % or more of X₁ is a structure represented by formula (1-1):

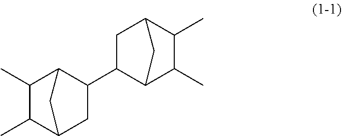

and 70 mol % or more of Y₁ is a structure represented by formula (D-1) and/or (D-2):

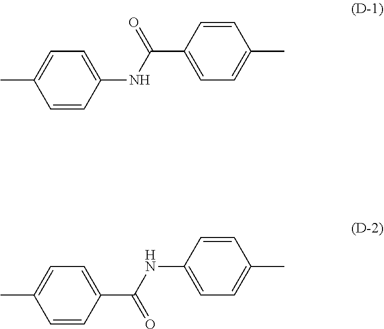

### TECHNICAL FIELD

The present invention relates to a polyimide precursor composition and a polyimide film having improved thermal decomposition resistance, which are suitably used for electronic device applications such as flexible device substrates.

### BACKGROUND ART

Polyimide films have been widely used in fields such as electric/electronic devices and semiconductors due to their excellent heat resistance, chemical resistance, mechanical strength, electrical properties, dimensional stability, and the like. On the other hand, with the coming of an advanced information society, the developments of optical materials such as an optical fiber and an optical waveguide in the field of optical communications, and a liquid crystal orientation film and a protective film for a color-filter in the field of display devices have recently advanced. In particular in the field of display devices, the study of a plastic substrate which is light-weight and excellent in flexibility as an alternative to a glass substrate, and the development of a display which is capable of being bent and rolled have been intensively conducted. Accordingly, there is need for a higher-performance optical material which may be used for such purposes.

In displays such as liquid crystal displays and organic EL displays, semiconductor elements such as TFTs are formed for driving each pixel. Therefore, the substrate is required to have heat resistance and dimensional stability. Since polyimide films have excellent heat resistance, chemical resistance, mechanical strength, electrical properties, dimensional stability, and the like, they are promising material for substrates in display applications.

Polyimide is generally colored in yellowish brown, which limits its use in transmissive devices such as liquid crystal displays equipped with a backlight. In recent years, however, polyimide films with excellent light transmittance have been developed, and expectations are rising for use as substrates in display applications (see Patent Documents 1 to 3).

Patent Documents 4 to 8 disclose a polyimide film obtained from a monomer component containing a tetracarboxylic dianhydride having two norbornane ring (bicyclo[2.2.1]heptane ring) structures bonded by a single bond.

### CITATION LIST

### Patent Document

Patent Document 1:WO 2012/011590
Patent Document 2:WO 2013/179727
Patent Document 3 :WO 2014/038715
Patent Document 4:WO 2017/030019
Patent Document 5:WO 2019/163703
Patent Document 6 :JP-A-2018-44180
Patent Document 7:WO 2018/051888
Patent Document 8:JP-A-2019-137828

### SUMMARY OF INVENTION

### Technical Problem

Known TFTs (thin film transistors) include amorphous silicon TFTs (a-Si TFTs), low temperature polysilicon TFTs (LTPS TFTs), high temperature polysilicon TFTs, and oxide TFTs. Even for an amorphous silicon TFT, which can be formed at a relatively low temperature, a film formation temperature of 300° C. to 400° C. is required. In particular, high-temperature deposition is advantageous for forming a semiconductor layer with high charge mobility. However, if the polyimide film has insufficient thermal decomposition resistance, for example, outgassing due to decomposition of the polyimide in the TFT formation process sometimes causes swelling between the polyimide film and the barrier film, or contamination of the manufacturing equipment. As a substrate of the flexible electronic device, a material that is stable at high temperatures is preferred. Namely, preferred is a film that is excellent in thermal decomposition resistance at the process temperature and generates extremely little gas. Also from the viewpoint of process margin, a film having a high thermal decomposition (starting) temperature is preferable.

In addition, since heating and cooling are repeated in the manufacturing process of flexible electronic devices, a polyimide film excellent in thermal properties with a sufficiently small coefficient of linear thermal expansion (CTE) is preferred as a substrate for flexible electronic devices.

The above Patent Documents 4 to 8 describe that the object is to provide a polyimide having excellent light transmittance and heat resistance. There is no disclosure of a polyimide film that satisfies both a sufficiently small coefficient of linear thermal expansion and thermal decomposition resistance at a high level while having light transmittance and mechanical properties within a satisfactory range. For example, Patent Document 6 evaluates heat resistance by glass transition temperature (Tg), but does not disclose a polyimide film having excellent thermal decomposition resistance. Accordingly, there is a strong demand for realization of a polyimide film having excellent thermal decomposition resistance that is optimal for flexible electronic device substrates.

Through an intensive research, the present inventors found a formulation that gives a polyimide with high heat resistance from a combination of a suitable tetracarboxylic acid component containing a tetracarboxylic acid dianhydride having two norbornane rings bonded by a single bond and a suitable diamine component. However, since the haze value of the film produced from these materials is high and turbidity is observed in the film, it has been found that these films are unsuitable for use as optical substrates for displays and the like.

Furthermore, as a result of research by the present inventors, the present inventors found that the polyimide precursor solution that gives polyimide with high heat resistance has poor storage stability and has a problem that fluidity decreases during storage.

The present invention has been made in view of the conventional problems, and an object of the present invention is to provide a precursor composition capable of producing a polyimide film having a sufficiently small coefficient of linear thermal expansion, excellent optical transparency and mechanical properties, and particularly excellent thermal decomposition resistance, and to provide a polyimide film obtained from the precursor composition.

Further, an object of one aspect of the present invention is to provide a precursor composition capable of producing a polyimide film having a small haze value and less turbidity preferably in addition to the above properties, and to provide a polyimide film obtained from the precursor composition.

Further, an object of one aspect of the present invention is to provide a precursor composition having excellent storage stability, preferably in addition to capability of producing a polyimide film having the above properties.

### Solution to Problem

The main disclosure of the present application is summarized as follows.
1. A polyimide precursor composition comprising:
a polyimide precursor having repeating units represented by the following general formula (I),
at least one imidazole compound in an amount more than 0.01 mol and 2 mol or less based on one mol of the repeating units of the polyimide precursor, and
a solvent;

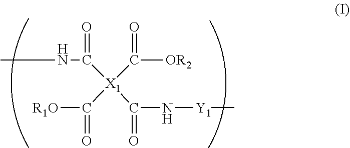

(wherein in general formula I, X₁ is a tetravalent aliphatic group or aromatic group, Y₁ is a divalent aliphatic group or aromatic group, R₁ and R₂ are each independently a hydrogen atom, an alkyl group having 1 to 6 carbon atoms or an alkylsilyl group having 3 to 9 carbon atoms; wherein 70 mol % or more of X₁ is a structure represented by formula (1-1):

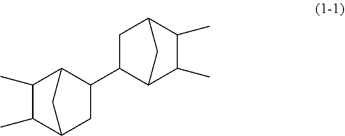

and 70 mol % or more of Y₁ is a structure represented by formula (D-1) and/or (D-2):

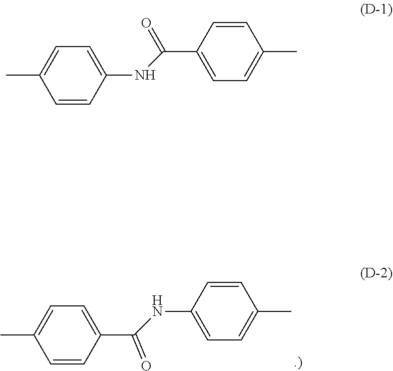

2. The polyimide precursor composition according to the above item 1, wherein the imidazole compound is at least one selected from the group consisting of 1,2-dimethylimidazole, 1-methylimidazole, 2-methylimidazole, 2-phenylimidazole, imidazole and benzimidazole.
3. The polyimide precursor composition according to the above item 1 or 2, wherein 90 mol % or more of X₁ has a structure represented by the formula (1-1).
4. The polyimide precursor composition according to any one of the above items 1 to 3, wherein a polyimide film obtained from the polyimide precursor composition has a 5% weight loss temperature of 515° C. or higher.
5. The polyimide precursor composition according to any one of the above items 1 to 4, wherein a polyimide film obtained from the polyimide precursor composition has a coefficient of linear thermal expansion of 20 ppm/K or less.
6. The polyimide precursor composition according to any one of the above items 1 to 5, wherein a polyimide film having a thickness of 10 μm obtained from the polyimide precursor composition has a haze value of less than 1.0%.
7. The polyimide precursor composition according to any one of the above items 1 to 6, which maintains fluidity when stored at 23° C. for 10 days in a sealed state.
8. A polyimide film obtained from the polyimide precursor composition according to any one of the above items 1 to 7.
9. A polyimide film/substrate laminate comprising:
a polyimide film obtained from the polyimide precursor composition according to any one of the above items 1 to 7, and
a substrate.
10. The laminate according to the above item 9, wherein the substrate is a glass substrate.
11. A method of producing a polyimide film/substrate laminate comprising:
(a) applying the polyimide precursor composition according to any one of the above items 1 to 7 onto a substrate; and
(b) heat-treating the polyimide precursor on the substrate to laminate a polyimide film on the substrate.
12. The method according to the above item 11, wherein the substrate is a glass substrate.
13. A method of manufacturing a flexible electronic device, comprising:
(a) applying the polyimide precursor composition according to any one of the above items 1 to 7 onto a substrate;
(b) heat-treating the polyimide precursor on the substrate;
(c) forming at least one layer selected from a conductor layer and a semiconductor layer on the polyimide film of the laminate; and
(d) separating the substrate and the polyimide film.
14. The method according to the above item 13, wherein the substrate is a glass substrate.

### Advantageous Effects of Invention

According to the present invention, provided is a precursor composition capable of producing a polyimide film having a sufficiently small coefficient of linear thermal expansion, excellent optical transparency, mechanical properties and thermal decomposition resistance, and also provide is a polyimide film obtained from the precursor composition.

Further, according to one aspect of the present invention, provided is a precursor composition capable of producing a polyimide film having a small haze value and less turbidity preferably in addition to the above properties, and provided is a polyimide film obtained from the precursor composition.

Further, according to one aspect of the present invention, provided is a precursor composition having excellent storage stability, preferably in addition to capability of producing a polyimide film having the above properties.

Further, according to one aspect of the present invention, provided are a polyimide film and a polyimide film/substrate laminate obtained using the above polyimide precursor composition. Furthermore, according to another aspect of the present invention, provided are a method for manufacturing a flexible electronic device and a flexible electronic device using the polyimide precursor composition.

### DESCRIPTION OF EMBODIMENTS

In the present application, the term “flexible (electronic) device” means that the device itself is flexible, and the device is usually completed by forming semiconductor layers (transistors, diodes and the like as elements) on a substrate. A “flexible (electronic) device” is distinguished from conventional devices such as COF (Chip On Film) in which a “hard” semiconductor element such as an IC chip is mounted on a FPC (Flexible Printed Circuit Board). However, in order to operate or control the “flexible (electronic) device” of the present application, “hard” semiconductor elements such as IC chips may be used in combination by mounting them on the flexible substrate, or electrically connecting them. Suitable flexible (electronic) devices include display devices such as liquid crystal displays, organic EL displays, and electronic papers, and light receiving devices such as solar cells and CMOS.

The polyimide precursor composition of the present invention will be described below, and then the method for producing a flexible electronic device will be described.

### <<Polyimide Precursor Composition>>

A polyimide precursor composition for forming a polyimide film comprises a polyimide precursor, an imidazole compound and a solvent. Both the polyimide precursor and the imidazole compound are dissolved in the solvent

The polyimide precursor has the following general formula (I):

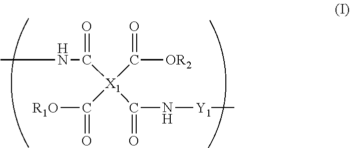

(wherein in general formula I, X₁ is a tetravalent aliphatic group or aromatic group, Y₁ is a divalent aliphatic group or aromatic group, R₁ and R₂ are each independently a hydrogen atom, an alkyl group having 1 to 6 carbon atoms or an alkylsilyl group having 3 to 9 carbon atoms.).
Particularly preferred are polyamic acids in which R₁ and R₂ are hydrogen atoms. When X₁ and Y₁ are aliphatic groups, the aliphatic group is preferably a group having an alicyclic structure.

Among the total repeating units in the polyimide precursor, preferably 70 mol % or more of X₁ has a structure represented by the following formula (1-1), namely, a structure derived from 2,2′-binorbornane-5,5′,6,6′-tetracarboxylic dianhydride (hereinafter referred to as BNBDA if necessary).

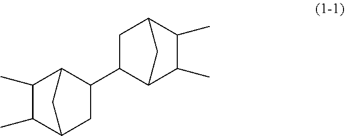

Among the total repeating units in the polyimide precursor, preferably 70 mol % or more of Y₁ has a structure represented by the following formula (D-1) and/or (D-2), namely, a structure derived from 4,4′-diaminobenzanilide (referred to as DABAN if necessary).

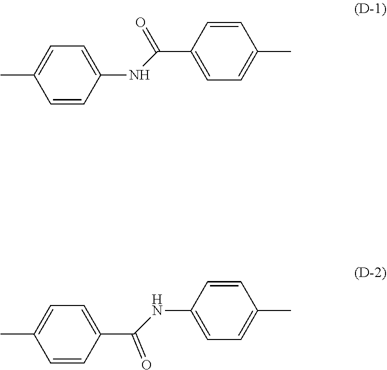

The use of a composition comprising such polyimide precursor enables the production of a polyimide film having a sufficiently small coefficient of linear thermal expansion, excellent optical transparency and mechanical properties, and particularly excellent thermal decomposition resistance.

The polyimide precursor will be explained by the monomers (tetracarboxylic acid component, diamine component, and other components) that give X₁ and Y₁ in the general formula (I), and then the production method will be explained.

In the present specification, the tetracarboxylic acid component means tetracarboxylic acid derivatives including tetracarboxylic acids, tetracarboxylic dianhydrides, and other tetracarboxylic acid silyl esters, tetracarboxylic acid esters, tetracarboxylic acid chlorides, and the like, which are used as raw materials for producing polyimide. Although not particularly limited, it is convenient to use a tetracarboxylic dianhydrides in terms of production, and an example using a tetracarboxylic dianhydride as a tetracarboxylic acid component will be described in the following explanation. The diamine component is diamine compounds having two amino groups (−NH₂), which is used as a raw material for producing polyimide.

In the present specification, polyimide film means both a film formed on a (carrier) substrate and present in the laminate, and a film obtained after peeling off the substrate. Moreover, the material which comprises the polyimide film, i.e., the material obtained by heat-processing (imidizing) the polyimide precursor composition, may be called “polyimide material”.

### <X₁ and Tetracarboxylic Acid Component>

As described above, in all repeating units in the polyimide precursor, preferably 70 mol % or more of X₁ is a structure represented by formula (1-1), and more preferably 80 mol % or more, further more preferably 90 mol % or more, and most preferably 95 mol % or more (100 mol % is also very preferred) of X₁ is a structure represented by formula (1-1). The tetracarboxylic dianhydride that gives the structure of formula (1-1) as X₁ is 2,2′-binorbornane-5,5′,6,6′-tetracarboxylic dianhydride (BNBDA).

In the present invention, as X₁, a tetravalent aliphatic group or aromatic group (abbreviated as “other X₁”) other than the structure represented by formula (1-1) is used within an amount that does not impair the effects of the present invention. That is, the tetracarboxylic acid component may contain, in addition to BNBDA, other tetracarboxylic acid derivative(s) in an amount that does not impair the effects of the present invention. The amount of the other tetracarboxylic acid derivative is 30 mol % or less (preferably less than 30 mol %), more preferably 20 mol % or less (preferably less than 20 mol %), further more preferably, 10 mol % or less (preferably less than 10 mol %) (0 mol % is also preferable), based on 100 mol % of the tetracarboxylic acid component.

When “other X₁” is a tetravalent group having an aromatic ring, it is preferably a tetravalent group having an aromatic ring having 6 to 40 carbon atoms.

Examples of the tetravalent group having an aromatic ring include the following groups.

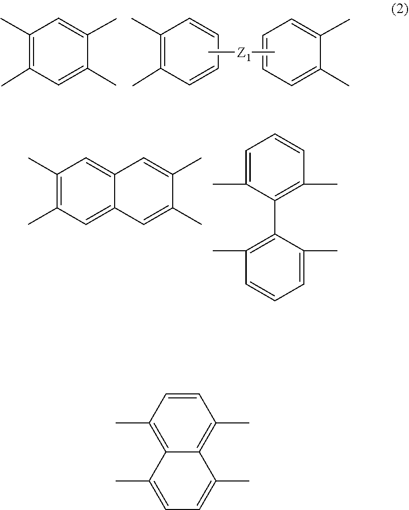

(wherein Z₁ is a direct bond, or any one of the following divalent groups:

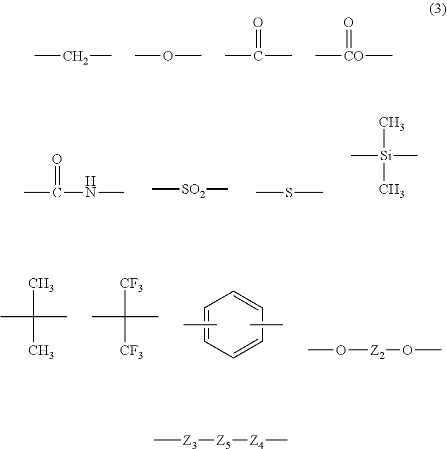

wherein Z₂ in the formula is a divalent organic group, Z₃ and Z₄ are each independently an amide bond, an ester bond and a carbonyl bond, and Z₅ is an organic group containing an aromatic ring.)

Specific examples of Z₂ include an aliphatic hydrocarbon group having 2 to 24 carbon atoms, and an aromatic hydrocarbon group having 6 to 24 carbon atoms.

Specific examples of Z₅ includes an aromatic hydrocarbon group having 6 to 24 carbon atoms

Because the obtained polyimide film may have both high heat resistance and high light transmittance, the following group is particularly preferred as the tetravalent group having an aromatic ring.

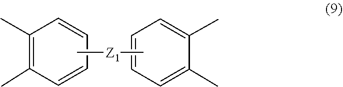

(wherein Z₁ is a direct bond, or a hexafluoroisopropylidene bond.)

Because the obtained polyimide film may have high heat resistance, high light transmittance, and low coefficient of linear thermal expansion, Z₁ is more preferably a direct bond.

In addition, preferred groups include a group in which Z₁ in the above formula (9) is a fluorenyl-containing group represented by the following formula (3A):

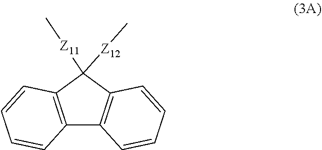

Z₁₁ and Z₁₂ are each independently, preferably the same, a single bond or a divalent organic group. Z₁₁ and Z₁₂ are preferably an organic group containing an aromatic ring, such as the formula (3A1):

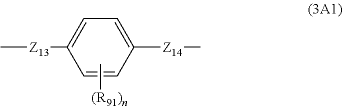

(Z₁₃ and Z₁₄ are each independently a single bond, —COO—, —OCO— or —O—, wherein when Z₁₄ is attached to a fluorenyl group, preferred is a structure in which Z₁₃ is —COO—, —OCO— or —O— and Z₁₄ is a single bond; R₉₁ is an alkyl group having 1 to 4 carbon atoms or a phenyl group, preferably methyl, and n is an integer of 0 to 4, and preferably 1.).

Examples of the tetracarboxylic acid component to provide a repeating unit of the chemical formula (1) in which X₁ is a tetravalent group having an aromatic ring include 2,2-bis(3,4-dicarboxyphenyl)hexafluoropropane, 4-(2,5-dioxotetrahydrofuran-3-yl)-1,2,3,4-tetrahydronaphthalene-1,2-dic arboxylic acid, pyromellitic acid, 3,3′,4,4′-benzophenone tetracarboxylic acid, 3,3′,4,4′-biphenyl tetracarboxylic acid, 2,3,3′,4′-biphenyl tetracarboxylic acid, 4,4′-oxydiphthalic acid, bis(3,4-dicarboxyphenyl)sulfone, m-terphenyl-3,4,3′,4′-tetracarboxylic acid, p-terphenyl-3,4,3′,4′-tetracarboxylic acid, biscarboxyphenyl dimethylsilane, bisdicarboxyphenoxydiphenyl sulfide, and sulfonyl diphthalic acid, and derivatives thereof, including tetracarboxylic dianhydride, tetracarboxylic acid silyl ester, tetracarboxylic acid ester, and tetracarboxylic acid chloride. Examples of the tetracarboxylic acid component to provide a repeating unit of the general formula (1) in which X₁ is a tetravalent group having a fluorine atom-containing aromatic ring include 2,2-bis(3,4-dicarboxyphenyl)hexafluoropropane, and derivatives thereof, including tetracarboxylic dianhydride, tetracarboxylic acid silyl ester, tetracarboxylic acid ester, and tetracarboxylic acid chloride. Furthermore, examples of preferred compound include (9H-fluorene-9,9-diyl)bis(2-methyl-4,1-phenylene)bis(1,3-dioxo-1,3-dihydroisobenzofuran-5-carboxylate). The tetracarboxylic acid component may be used alone or in combination of a plurality of types.

When “other X₁” is a tetravalent group having an alicyclic structure, a tetravalent group having an alicyclic structure which has 4 to 40 carbon atoms is preferred, and it is more preferred that the group has at least one aliphatic 4- to 12-membered ring, more preferably an aliphatic 4-membered ring or an aliphatic 6-membered ring. Preferred examples of the tetravalent group having an aliphatic 4-membered ring or an aliphatic 6-membered ring include the following groups.

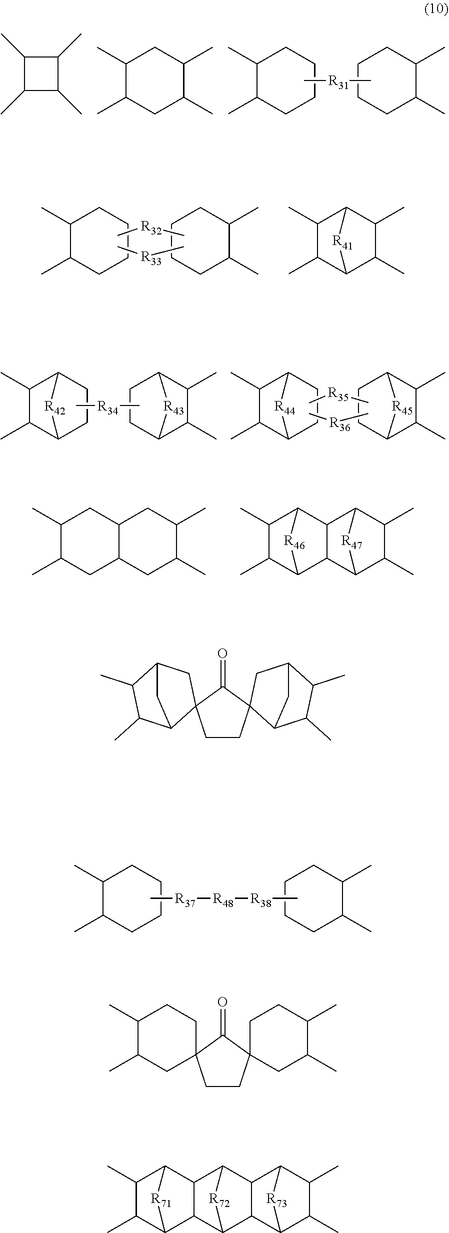

(wherein R₃₁ to R₃₈ are each independently a direct bond, or a divalent organic group; and R₄₁ to R₄₇ and R₇₁ to R₇₃ each independently represent one selected from the group consisting of groups represented by the formulas: —CH₂—, —CH═CH—, —CH₂CH₂—, —O— and —S—. R₄₈ is an organic group having an aromatic ring or an alicyclic structure.)

Specific examples of R₃₁, R₃₂, R₃₃, R₃₄, R₃₅, R₃₆, R₃₇ and R₃₈ include a direct bond, or an aliphatic hydrocarbon group having 1 to 6 carbon atoms, or an oxygen atom (—O—), a sulfur atom (—S—), a carbonyl bond, an ester bond, and an amide bond.

Examples of the organic group having an aromatic ring as R₄₈ include the following groups.

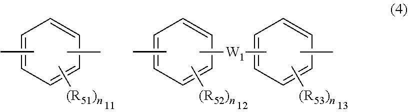

(wherein W₁ is a direct bond, or a divalent organic group; n₁₁ to n₁₃ each independently represent an integer of 0 to 4; and R₅₁, R₅₂ and R₅₃ are each independently an alkyl group having 1 to 6 carbon atoms, a halogen group, a hydroxyl group, a carboxyl group, or a trifluoromethyl group.)

Specific examples of W₁ include divalent groups represented by the formula (5) as described below, and divalent groups represented by the formula (6) as described below.

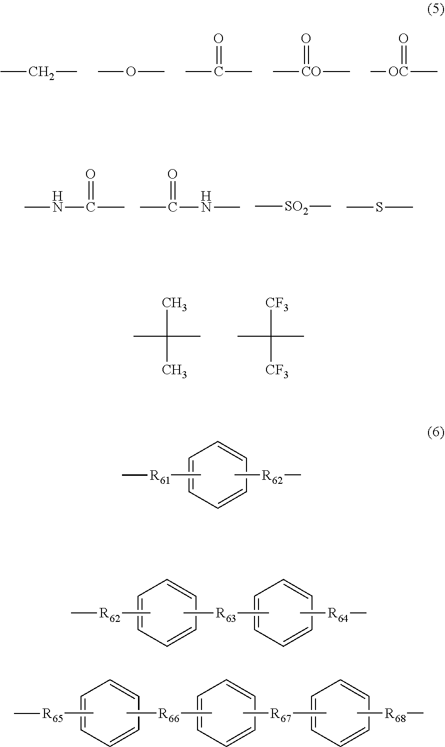

(wherein R₆₁ to R₆₈ in the formula (6) each independently represent any one of the divalent groups represented by the formula (5).)

Because the obtained polyimide may have high heat resistance, high light transmittance, and low coefficient of linear thermal expansion, the following groups are particularly preferred as the tetravalent group having an alicyclic structure.

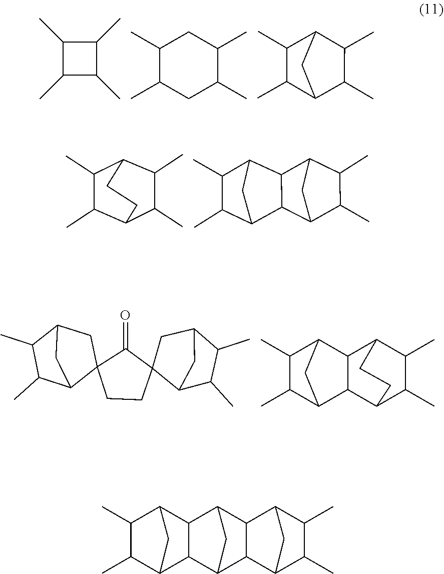

Examples of the tetracarboxylic acid component to provide a repeating unit of the chemical formula (1) in which X1 is a tetravalent group having an alicyclic structure include 1,2,3,4-cyclobutane tetracarboxylic acid, isopropylidenediphenoxybisphthalic acid, cyclohexane-1,2,4,5-tetracarboxylic acid, [1,1′-bi(cyclohexane)]-3,3′,4,4′-tetracarboxylic acid, [1,1′-bi(cyclohexane)]-2,3,3′,4′-tetracarboxylic acid, [1,1′-bi(cyclohexane)]-2,2′,3,3′-tetracarboxylic acid, 4,4′-methylenebis(cyclohexane-1,2-dicarboxylic acid), 4,4′-(propane-2,2-diyl)bis(cyclohexane-1,2-dicarboxylic acid), 4,4′-oxybis(cyclohexane-1,2-dicarboxylic acid), 4,4′-thiobis(cyclohexane-1,2-dicarboxylic acid), 4,4′-sulfonyl bis(cyclohexane-1,2-dicarboxylic acid), 4,4′-(dimethylsilanediyl)bis (cyclohexane-1,2-dicarboxylic acid), 4,4′-(tetrafluoropropane-2,2-diyl)bis (cyclohexane-1,2-dicarboxylic acid), octahydropentalene-1,3,4,6-tetracarboxylic acid, bicyclo[2.2.1]heptane-2,3,5,6-tetracarboxylic acid, 6-(carboxymethyl)bicyclo[2.2.1]heptane-2,3,5-tricarboxylic acid, bicyclo[2.2.2]octane-2,3,5,6-tetracarboxylic acid, bicyclo[2.2.2]octa-5-ene-2,3,7,8-tetracarboxylic acid, tricyclo[4.2.2.02,5]decane-3,4,7,8-tetracarboxylic acid, tricyclo[4.2.2.02,5]deca-7-ene-3,4,9,10-tetracarboxylic acid, 9-oxatricyclo[4.2.1.02,5]nonane-3,4,7,8-tetracarboxylic acid, norbornane-2-spiro-α-cyclopentanone-α′-spiro-2″-norbornane-5,5″,6,6″-tetracarboxylic acid, (4arH,8acH)-decahydro-1t,4t:5c,8c-dimethanonaphthalene-2c,3c,6c,7c-tetracarboxylic acid, (4arH,8acH)-decahydro-1t,4t:5c,8c-dimethanonaphthalene-2t,3t,6c,7c-tetracarboxylic acid, decahydro-1,4-ethano-5,8-methanonaphthalene-2,3,6,7-tetracarboxylic acid, and tetradecahydro-1,4:5,8:9,10-trimethanoanthracene-2,3,6,7-tetracarboxylic acid and derivatives thereof, including tetracarboxylic dianhydride, tetracarboxylic acid silyl ester, tetracarboxylic acid ester, and tetracarboxylic acid chloride. The tetracarboxylic acid component may be used alone or in combination of a plurality of types.

### <Y₁ and Diamine Component>

As described above, preferably 70 mol % or more of Y₁ in the total repeating units in the polyimide precursor is a structure represented by formula (D-1) and/or (D-2), and more preferably 80 mol % or more, further more preferably 90 mol % or more (100 mol % is also preferred) of Y₁ is a structure represented by formula (D-1) and/or (D-2). The diamine compound that gives the structures of the formulas (D-1) and (D-2) as Y₁ is 4,4′-diaminobenzanilide (abbreviation: DABAN).

In the present invention, as Y₁, a divalent aliphatic group or aromatic group (abbreviated as “other Y₁”) other than the structures represented by formulas (D-1) and (D-2) may be used within an amount that does not impair the effect of the invention. That is, the diamine component may contain other diamine compound(s), in addition to DABAN, in amounts that do not impair the effects of the present invention. The amount of the other diamine compound is 30 mol % or less (preferably less than 30 mol %), more preferably 20 mol % or less (preferably less than 20 mol %), further more preferably 10 mol % or less (preferably less than 10 mol %) (0 mol % is also preferred), based on 100 mol % of the diamine component.

In a preferred embodiment of the present invention, the proportion of structures of formula (D-1) and/or (D-2) in Y₁ is less than 100 mol %. In this case, the other Y₁ preferably includes a structure represented by formula (G-1):

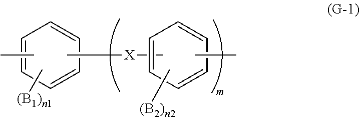

(wherein m represents 0 to 3, n₁ and n₂ each independently represent an integer of 0 to 4, B₁ and B₂ each independently represent a group selected from the group consisting of an alkyl group having 1 to 6 carbon atoms, a halogen group and a fluoroalkyl group having 1 to 6 carbon atoms, X each independently represents a direct bond or a group selected from the group consisting of formulas: —NHCO—, —CONH—, —COO—, —OCO—. However, the above formulas (D-1) and (D-2) are excluded.).

m is preferably 0, 1 or 2, n₁ and n₂ are preferably 0 or 1, B₁ and B₂ are preferably methyl or trifluoromethyl. Examples thereof include a structure where m=0 and n₁=0, a structure where m=1 and X is a direct bond or —COO—, —OCO—, and n₁=n₂=0 or 1, and a structure where m=2 and X is a direct bond or—COO— and —OCO—. A particularly preferred structure is that where m=1 and X is a direct bond.

The structure of formula (G-1) is contained in Y₁ in a proportion of preferably more than 0 mol % and 30 mol % or less, more preferably more than 5 mol % and 30 mol % or less. By including the structure of formula (G-1), mechanical properties such as break strength and optical properties can be improved. Structures of formula (G-1) include formulas (B-1) and/or (B-2):

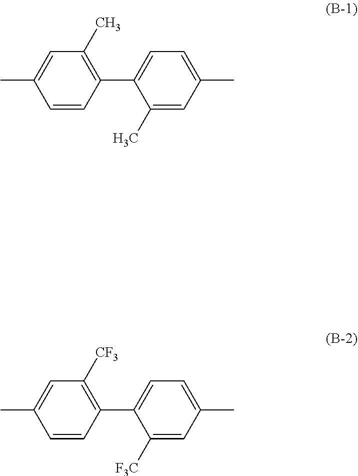

Further, as Y₁, “other Y₁” other than formula (D-1), formula (D-2) and formula (G-1) may be contained at a ratio of 10 mol % or less (preferably 0 mol %).

When “other Yi” other than formula (D-1) is a divalent group having an aromatic ring, a divalent group having an aromatic ring having 6 to 40 carbon atoms, more preferably 6 to 20 carbon atoms, is preferred.

Examples of the divalent group having an aromatic ring include the following groups. However, a group embraced by formula (G-1) is excluded.

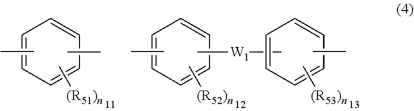

(wherein W₁ is a direct bond, or a divalent organic group; n₁₁ to n₁₃ each independently represent an integer of 0 to 4; and R₅₁, R₅₂ and R₅₃ are each independently an alkyl group having 1 to 6 carbon atoms, a halogen group, a hydroxyl group, a carboxyl group, or a trifluoromethyl group.)

Specific examples of W₁ include a direct bond and divalent groups represented by the formula (5) as described below, and divalent groups represented by the formula (6) as described below.

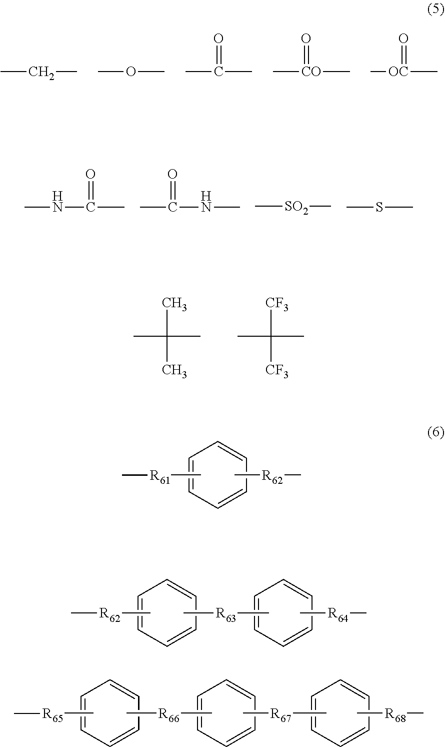

(wherein R₆₁ to R₆₈ in the formula (6) each independently represents a direct bond or any one of the divalent groups represented by the formula (5).)

Because the obtained polyimide may have high heat resistance, high light transmittance, and low coefficient of linear thermal expansion, W₁ herein is particularly preferably a direct bond, or one selected from the group consisting of groups represented by the formulas: —NHCO—, —CONH—, —COO— and —OCO—. In addition, W₁ is particularly preferably any one of the divalent groups represented by the formula (5) in which R61 to R68 are a direct bond, or one selected from the group consisting of groups represented by the formulas: —NHCO—, —CONH—, —COO— and —OCO—. However, if —NHCO— or —CONH— is selected, “other Y₁” will be selected so that it is different from formulas (D-1) and (D-2).

In addition, preferred groups include a group in which W₁ in the above formula (4) is a fluorenyl-containing group represented by the following formula (3B):

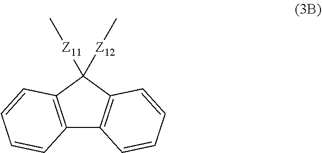

Z₁₁ and Z₁₂ are each independently, preferably the same, a single bond or a divalent organic group. Z₁₁ and Z₁₂ are preferably an organic group containing an aromatic ring, such as the formula (3B1):

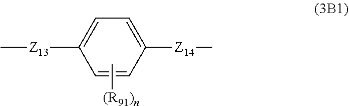

(Z₁₃ and Z₁₄ are each independently a single bond, —COO—, —OCO— or —O—, wherein when Z₁₄ is attached to a fluorenyl group, preferred is a structure in which Z₁₃ is —COO—, —OCO— or —O— and Z₁₄ is a single bond; R₉₁ is an alkyl group having 1 to 4 carbon atoms or a phenyl group, preferably methyl, and n is an integer of 0 to 4, and preferably 1.).

Another preferred group includes a compound in which W₁ in the above formula (4) is a phenylene group, that is, terphenyldiamine compounds, and particularly preferred are compounds in which all bondings are in para position.

Another preferred group includes a compound in which W₁ in the above formula (4) is a phenyl ring as depicted at first in formula (6) wherein R₆₁ and R₆₂ are 2,2-propylidene groups.

Still another preferred group includes a compound in which W₁ in the above formula (4) is represented by formula (3B2):

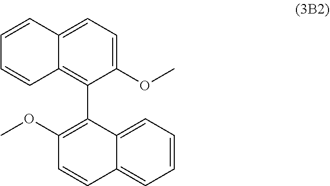 [SMILES: COc1ccc2ccccc2c1-c1c(OC)ccc2ccccc12]

Examples of the diamine component to provide a repeating unit of the general formula (1) in which Y₁ is a divalent group having an aromatic ring include p-phenylenediamine, m-phenylenediamine, benzidine, 3,3′-diamino-biphenyl, 2,2′-bis(trifluoromethyl)benzidine, 3,3′-bis(trifluoromethyl) benzidine, m-tolidine, 3,4′-diaminobenzanilide, N,N′-bis(4-aminophenyl)terephthalamide, N,N′-p-phenylenebis(p-amino benzamide), 4-aminophenoxy-4-diaminobenzoate, bis(4-aminophenyl) terephthalate, biphenyl-4,4′-dicarboxylic acid bis(4-aminophenyl)ester, p-phenylenebis(p-aminobenzoate), bis(4-aminophenyl)-[1,1′-biphenyl]-4,4′-dicarboxylate, [1,1′-biphenyl]-4,4′-diyl bis(4-aminobenzoate), 4,4′-oxydianiline, 3,4′-oxydianiline, 3,3′-oxydianiline, p-methylenebis(phenylenediamine), 1,3-bis(4-aminophenoxy)benzene, 1,3-bis(3-aminophenoxy)benzene, 1,4-bis(4-aminophenoxy)benzene, 4,4′-bis(4-aminophenoxy)biphenyl, 4,4′-bis(3-amino phenoxy)biphenyl, 2,2-bis(4-(4-aminophenoxy)phenyl)hexafluoropropane, 2,2-bis(4-aminophenyl)hexafluoropropane, bis(4-aminophenyl)sulfone, 3,3′-bis(trifluoromethyl)benzidine, 3,3′-bis((aminophenoxy)phenyl)propane, 2,2′-bis(3-amino-4-hydroxyphenyl)hexafluoropropane, bis(4-(4-aminophenoxy) diphenyl)sulfone, bis(4-(3-aminophenoxy)diphenyl)sulfone, octafluorobenzidine, 3,3′-dimethoxy-4,4′-diaminobiphenyl, 3,3′-dichloro-4,4′-diaminobiphenyl, 3,3′-difluoro-4,4′-diaminobiphenyl, 2,4-bis(4-aminoanilino)-6-amino-1,3,5-triazine, 2,4-bis(4-aminoanilino)-6-methylamino-1,3,5-triazine, 2,4-bis(4-aminoanilino)-6-ethylamino-1,3,5-triazine, and 2,4-bis(4-amino anilino)-6-anilino-1,3,5-triazine. Examples of the diamine component to provide a repeating unit of the general formula (1) in which Y1 is a divalent group having a fluorine atom-containing aromatic ring include 2,2′-bis (trifluoromethyl)benzidine, 3,3′-bis(trifluoromethyl)benzidine, 2,2-bis[4-(4-aminophenoxy)phenyl]hexafluoropropane, 2,2-bis(4-aminophenyl) hexafluoropropane, and 2,2′-bis(3-amino-4-hydroxyphenyl)hexafluoropropane. In addition, preferred diamine compounds include 9,9-bis(4-aminophenyl)fluorene, 4,4′-(((9H-fluorene-9,9-diyl)bis([1,1′-biphenyl]-5,2-diyl))bis(oxy))diamine, [1,1′:4′,1″-terphenyl]-4,4″-diamine, 4,4′-([1,1′-binaphthalene]-2,2′-diylbis(oxy))diamine. The diamine component may be used alone or in combination of a plurality of types.

When “other Y₁” is a divalent group having an alicyclic structure, a divalent group having an alicyclic structure which has 4 to 40 carbon atoms is preferred, and it is more preferred that the group has at least one aliphatic 4- to 12-membered ring, more preferably an aliphatic 6-membered ring.

Examples of the divalent group having an alicyclic structure include the following groups.

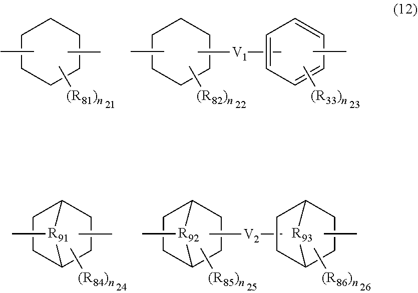

(wherein V₁ and V₂ are each independently a direct bond, or a divalent organic group; n₂₁ to n₂₆ each independently represent an integer of 0 to 4; R₈₁ to R₈₆ are each independently an alkyl group having 1 to 6 carbon atoms, a halogen group, a hydroxyl group, a carboxyl group, or a trifluoromethyl group; and R₉₁, R₉₂ and R₉₃ are each independently one selected from the group consisting of groups represented by the formulas: —CH₂—, —CH═CH—, —CH₂CH₂—, —O— and —S—)

Specific examples of V₁ and V₂ include a direct bond ans divalent groups represented by the formula (5) as described above.

Because the obtained polyimide may have both high heat resistance and low coefficient of linear thermal expansion, the following group is particularly preferred as the divalent group having an alicyclic structure.

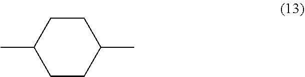

Among them, the following group is preferred as the divalent group having an alicyclic structure.

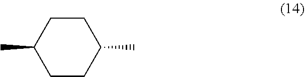

Examples of the diamine component to provide a repeating unit of the general formula (1) in which Y1 is a divalent group having an alicyclic structure include 1,4-diaminocyclohexane, 1,4-diamino-2-methylcyclohexane, 1,4-diamino-2-ethylcyclohexane, 1,4-diamino-2-n-propylcyclohexane, 1,4-diamino-2-isopropylcyclohexane, 1,4-diamino-2-n-butylcyclohexane, 1,4-diamino-2-isobutylcyclohexane, 1,4-diamino-2-sec-butylcyclohexane, 1,4-diamino-2-tert-butylcyclohexane, 1,2-diaminocyclohexane, 1,3-diamino cyclobutane, 1,4-bis(aminomethyl)cyclohexane, 1,3-bis(aminomethyl) cyclohexane, diaminobicycloheptane, diaminomethylbicycloheptane, diaminooxybicycloheptane, diaminomethyloxybicycloheptane, isophoronediamine, diaminotricyclodecane, diaminomethyltricyclodecane, bis(aminocyclohexyl)methane, bis(aminocyclohexyl)isopropylidene, 6,6′-bis(3-aminophenoxy)-3,3,3′,3′-tetramethyl-1,1′-spirobiindane, and 6,6′-bis(4-aminophenoxy)-3,3,3′,3′-tetramethyl-1,1′-spirobiindane. The diamine component may be used alone or in combination of a plurality of types.

As the tetracarboxylic acid component and the diamine component that give the repeating unit represented by the general formula (I), any of aliphatic tetracarboxylic acids (especially dianhydrides) and/or aliphatic diamines other than alicyclic compounds may be used. However, the content thereof is preferably less than 30 mol %, more preferably less than 20 mol %, and further more preferably less than 10 mol % (including 0%).

When the structure represented by formula (4) is incorporated as “other Y₁”, namely, in terms of specific compounds, a diamine compound such as p-phenylenediamine, 3,3′-bis(trifluoromethyl)benzidine, m-tolysine, 4,4′-bis(4-aminophenoxy)biphenyl and diaminodiphenyl ether is incorporated, the resulting polyimide film may have improved light transmittance and other physical properties. In addition, when the structure represented by formula (3B) is incorporated as “other Y₁”, namely, in terms of specific compounds, a diamine compound such as 9,9-bis(4-aminophenyl)fluorene is incorpoated, the resulting polyimide film may have improve Tg, and reduced retardation in the film thickness direction.

A polyimide precursor can be produced from the above tetracarboxylic acid component and diamine component. According to the chemical structures of R₁ and R₂, the polyimide precursor used in the present invention (polyimide precursor comprising at least one repeating unit represented by the formula (I)) may be classified into:
1) polyamic acid (R₁ and R₂ are hydrogen),
2) polyamic acid ester (at least part of R₁ and R₂ is alkyl group), and
3) 4) polyamic acid silyl ester (at least part of R₁ and R₂ is alkylsilyl group).
   Each class of the polyimide precursor may be easily produced by the production methods as described below. However, the method for producing the polyimide precursor used in the present invention is not limited to the production methods as described below.

### 1) Polyamic Acid

The polyimide precursor may be suitably obtained, in the form of a polyimide precursor solution, by reacting a tetracarboxylic dianhydride as a tetracarboxylic acid component and a diamine component in a substantially equimolar amount, preferably in a molar ratio of the diamine component to the tetracarboxylic acid component [molar number of the diamine component/molar number of the tetracarboxylic acid component] of 0.90 to 1.10, more preferably 0.95 to 1.05, in a solvent at a relatively low temperature of 120° C. or less, for example, while suppressing the imidization.

More specifically, the polyimide precursor may be obtained by dissolving the diamine in an organic solvent or water, adding the tetracarboxylic dianhydride to the resulting solution gradually while stirring the solution, and then stirring the solution at 0° C. to 120° C., preferably 5° C. to 80° C., for 1 hour to 72 hours, although the production method is not limited thereto. When they are reacted at 80° C. or more, the molecular weight may vary depending on the temperature history in the polymerization and the imidization may proceed by heat, and therefore the polyimide precursor may not be stably produced. The sequence of the addition of the diamine and the tetracarboxylic dianhydride in the production method as described above is preferred because the molecular weight of the polyimide precursor is apt to increase. Meanwhile, the sequence of the addition of the diamine and the tetracarboxylic dianhydride in the production method as described above may be reversed, and the sequence is preferred because the amount of the precipitate is reduced. When water is used as the solvent, an imidazole such as 1,2-dimethylimidazole, or a base such as triethylamine is preferably added thereto preferably in an amount of 0.8 equivalents or more relative to the carboxyl group of the formed polyamic acid (polyimide precursor).

### 2) Polyamic Acid Ester

A diester dicarboxylic acid chloride may be obtained by reacting a tetracarboxylic dianhydride and an arbitrary alcohol to provide a diester dicarboxylic acid, and then reacting the diester dicarboxylic acid and a chlorinating agent (thionyl chloride, oxalyl chloride, and the like). The polyimide precursor may be obtained by stirring the diester dicarboxylic acid chloride and a diamine at —20° C. to 120° C., preferably —5° C. to 80° C., for 1 hour to 72 hours. When they are reacted at 80° C. or more, the molecular weight may vary depending on the temperature history in the polymerization and the imidization may proceed by heat, and therefore the polyimide precursor may not be stably produced. The polyimide precursor may also be easily obtained by dehydrating/condensing a diester dicarboxylic acid and a diamine by the use of a phosphorus-based condensing agent, a carbodiimide condensing agent, or the like.

The polyimide precursor obtained by the method is stable, and therefore may be subjected to purification, including reprecipitation in which a solvent such as water and alcohols is added thereto.

### 3) Polyamic Acid Silyl Ester (Indirect Method)

A silylated diamine may be obtained by reacting a diamine and a silylating agent in advance. The silylated diamine may be purified by distillation, or the like, as necessary. And then, the polyimide precursor may be obtained by dissolving the silylated diamine in a dehydrated solvent, adding a tetracarboxylic dianhydride to the resulting solution gradually while stirring the solution, and then stirring the solution at 0° C. to 120° C., preferably 5° C. to 80° C., for 1 hour to 72 hours. When they are reacted at 80° C. or more, the molecular weight may vary depending on the temperature history in the polymerization and the imidization may proceed by heat, and therefore the polyimide precursor may not be stably produced.

### 4) Polyamic Acid Silyl Ester (Direct Method)

The polyimide precursor may be obtained by mixing a polyamic acid solution obtained by the method 1) and a silylating agent, and then stirring the resulting mixture at 0° C. to 120° C., preferably 5° C. to 80° C., for 1 hour to 72 hours. When they are reacted at 80° C. or more, the molecular weight may vary depending on the temperature history in the polymerization and the imidization may proceed by heat, and therefore the polyimide precursor may not be stably produced.

As for the silylating agent to be used in the method 3) and the method 4), the use of a silylating agent containing no chlorine is preferred because it is unnecessary to purify the silylated polyamic acid, or the obtained polyimide. Examples of the silylating agent containing no chlorine atom include N,O-bis(trimethylsilyl)trifluoroacetamide, N,O-bis(trimethylsilyl) acetamide, and hexamethyldisilazane. Among them, N,O-bis(trimethylsilyl) acetamide, and hexamethyldisilazane are particularly preferred, because they contain no fluorine atom and are inexpensive.

Meanwhile, in the silylation reaction of the diamine in the method 3), an amine catalyst such as pyridine, piperidine and triethylamine may be used so as to accelerate the reaction. The catalyst may be used, as it is, as a catalyst for the polymerization of the polyimide precursor.

As the solvent used in the production of the polyimide precursor, water, or aprotic solvents such as N,N-dimethylformamide, N,N-dimethylacetamide, N-methyl-2-pyrrolidone, N-ethyl-2-pyrrolidone, 1,3-dimethyl-2-imidazolidinone and dimethyl sulfoxide, for example, are preferred. However, any solvent may be used without any trouble on the condition that the starting monomer components and the formed polyimide precursor can be dissolved in the solvent, and therefore the solvent is not limited to the structures. As the solvent, water, or amide solvents such as N,N-dimethylformamide, N,N-dimethylacetamide, N-methyl-pyrrolidone and N-ethyl-2-pyrrolidone; cyclic ester solvents such as γ-butyrolactone, γ-valerolactone, δ-valerolactone, γ-caprolactone, ε-caprolactone and α-methyl-γ-butyrolactone; carbonate solvents such as ethylene carbonate and propylene carbonate; glycol solvents such as triethylene glycol; phenol solvents such as m-cresol, p-cresol, 3-chlorophenol and 4-chlorophenol; acetophenone, 1,3-dimethyl-2-imidazolidinone, sulfolane, dimethylsulfoxide, and the like may be preferably employed. In addition, other common organic solvents, namely, phenol, o-cresol, butyl acetate, ethyl acetate, isobutyl acetate, propyleneglycol methyl acetate, ethyl cellosolve, butyl cellosolve, 2-methyl cellosolve acetate, ethyl cellosolve acetate, butyl cellosolve acetate, tetrahydrofuran, dimethoxyethane, diethoxyethane, dibutyl ether, diethylene glycol dimethyl ether, methyl isobutyl ketone, diisobutyl ketone, cyclopentanone, cyclohexanone, methyl ethyl ketone, acetone, butanol, ethanol, xylene, toluene, chlorobenzene, turpentine, mineral spirits, petroleum naphtha-based solvents, and the like may be used. The solvent may be used in combination of a plurality of types.

The production of the polyimide precursor is not particularly limited, but the reaction is carried out by charging the monomers and the solvent at a concentration such that the solid content concentration (polyimide-converted mass concentration) of the polyimide precursor is, for example, 5 to 45% by mass.

The logarithmic viscosity of the polyimide precursor in a N-methyl-2-pyrrolidone solution at a concentration of 0.5 g/dL at 30° C. may be preferably 0.2 dL/g or more, more preferably 0.3 dL/g or more, particularly preferably 0.4 dL/g or more, although the logarithmic viscosity is not limited thereto. When the logarithmic viscosity is 0.2 dL/g or more, the molecular weight of the polyimide precursor is high, and therefore the obtained polyimide may have excellent mechanical strength and heat resistance.

### <Imidazole Compound>

The polyimide precursor composition contains at least one kind of imidazole compound. The imidazole compound is not particularly limited as long as it has an imidazole skeleton, and examples thereof include 1,2-dimethylimidazole, 1-methylimidazole, 2-methylimidazole, 2-phenylimidazole, imidazole and benzimidazole. From the viewpoint of storage stability of the polyimide precursor composition, 2-phenylimidazole and benzimidazole are preferred. The imidazole compound may be used in combination of two or more compounds.

The content of the imidazole compound in the polyimide precursor composition may be appropriately selected in consideration of the balance between the effect of addition and the stability of the polyimide precursor composition. The amount of the imidazole compound is preferably from more than 0.01 mol to 2 mol or less with respect to 1 mol of repeating units of the polyimide precursor. Addition of an imidazole compound is effective in improving light transmittance, coefficient of linear thermal expansion and/or mechanical properties. On the other hand, if the imidazole compound content is too high, the storage stability of the polyimide precursor composition may deteriorate in some cases.

The content of the imidazole compound is, with respect to 1 mol of repeating units of the polyimide precursor, more preferably 0.02 mol or more, further more preferably 0.025 mol or more, further more preferably 0.05 mol or more, and preferably 1.5 mol or less, further more preferably 1.2 mol or less, further more preferably 1.0 mol or less, further more preferably 0.8 mol or less, and most preferably 0.6 mol or less..

Further, in intensive research by the present inventors, when a film was formed from a solution containing a polyimide precursor having a repeating unit represented by the general formula (I) and not containing an imidazole compound, the film had a large haze value and turbidity was observed, and therefore it was found to be unsuitable for use as an optical substrate for displays and the like. When a film was produced from the polyimide precursor composition of the present invention containing an imidazole compound, the haze value was small and the transparency (no turbidity) was excellent. Therefore, it is particularly suitable for optoelectronic device substrates such as display applications among flexible electronic devices.

From this point of view, the present application also discloses a method for improving the haze value of a polyimide film obtained from a polyimide precursor solution comprising a polyimide precursor having the repeating unit represented by the general formula (I) and a solvent, wherein the method comprises to include, into the composition, at least one imidazole compound in an amount of more than 0.01 to 2 mol or less per 1 mol of repeating units of the polyimide precursor.

Furthermore, according to a finding obtained in intensive research by the present inventors, a polyimide precursor solution (not containing an imidazole compound) having the repeating unit represented by the general formula (I) has poor storage stability and the fluidity thereof decreased during storage. On the other hand, the polyimide precursor composition of the present invention to which an imidazole compound is added has excellent storage stability, and is particularly advantageous from the viewpoint of transportation, distribution and inventory storage. As examples of a composition that tends to deteriorate storage stability when no imidazole compound is included, a case where the polyimide-converted mass concentration (solid content concentration) is high can be raised. This effect can be clearly confirmed particularly when it is applied to a solution having a solid content concentration of 10% by mass or more, preferably 15% by mass or more. In addition, the composition in which this effect is particularly effective is a composition having a large proportion of formula (1-1) in X₁ of general formula (I), and/or a composition having a large proportion of the formula (D-1) and/or (D- 2) in Y₁. In particular, a large effect can be obtained for compositions in which the proportion of formula (1-1) in X₁ is 80% or more, preferably 90% or more, and the proportion of formula (D-1) and/or (D-2) in Y₁ is 80% or more, preferably 90% or more.

From this point of view, the present application also discloses a method for improving the storage stability of a polyimide precursor solution comprising a polyimide precursor having the repeating unit represented by the general formula (I) and a solvent and having poor storage stability, wherein the method comprises to include, into the composition, at least one imidazole compound in an amount of more than 0.01 mol to 2 mol or less per 1 mol of repeating units of the polyimide precursor.

### <Formulation of Polyimide Precursor Composition]

The polyimide precursor composition used in the present invention comprises at least one polyimide precursor, at least one imidazole compound as described above, and a solvent.

As the solvent, those mentioned above as the solvent used in preparing the polyimide precursor can be used. Generally, the solvent used in preparing the polyimide precursor may be used as it is, i.e., as the polyimide precursor solution as prepared. But, if necessary, it may be used after being diluted or concentrated. The imidazole compound is present dissolved in the polyimide precursor composition. Although the concentration of the polyimide precursor is not particularly limited, it is usually 5 to 45% by mass in terms of polyimide-converted mass concentration (solid content concentration). Here, the polyimide-converted mass is the mass when all repeating units are completely imidized.

Although the viscosity (rotational viscosity) of the polyimide precursor composition of the present invention is not limited thereto, the rotational viscosity, which is measured with an E-type rotational viscometer at a temperature of 25° C. and at a shearing speed of 20 sec⁻¹, may be preferably 0.01 to 1000 Pa-sec, more preferably 0.1 to 100 Pa-sec. In addition, thixotropy may be imparted, as necessary. When the viscosity is within the above-mentioned range, the composition is easy to handle during the coating or the film formation, and the varnish is less repelled and has excellent leveling property, and therefore a good film may be obtained.

The polyimide precursor composition of the present invention may comprise a chemical imidizing agent (an acid anhydride such as acetic anhydride, and an amine compound such as pyridine and isoquinoline), an anti-oxidizing agent, UV absorber, a filler (including an inorganic particle such as silica), a dye, a pigment, a coupling agent such as a silane coupling agent, a primer, a flame retardant, a defoaming agent, a leveling agent, a rheology control agent (flow-promoting agent), and the like, as necessary.

The polyimide precursor composition can be prepared by adding and mixing an imidazole compound or a solution of an imidazole compound to the polyimide precursor solution obtained by the method described above. Alternatively, in the presence of an imidazole compound, the tetracarboxylic acid component and the diamine component may be reacted.

### <<Applications of Polyimide Precursor Composition and Physical Properties of Film>>

Polyimides and polyimide films can be produced using the polyimide precursor composition of the present invention. The production method is not particularly limited, and any known imidization method can be suitably applied. Forms of the obtained polyimide include films, laminates of polyimide films and other substrates, coating films, powders, beads, moldings, foams, and the like.

Depending on the application, the thickness of the polyimide film is preferably 1 μm or more, more preferably 2 μm or more, further more preferably 5 μm or more, and for example 250 μm or less, preferably 150 μm or less, more preferably 100 μm or less, and further more preferably 50 μm or less.

The polyimide film of the present invention is excellent in light transmittance, mechanical properties, thermal properties, and heat resistance. Here, “heat resistance” is related to phase change (indicated by glass transition temperature, melting temperature, etc.) and thermal decomposition (indicated by weight loss). Since the two are different phenomena, they are not directly related. The polyimide and polyimide film of the present invention are excellent in both glass transition temperature (Tg) and thermal decomposition resistance, and particularly superior to conventional polyimides in thermal decomposition resistance.

Evaluation of the thermal decomposition resistance of the polyimide film (or the polyimide that constitutes it) can be set based on the properties required in the manufacturing process of flexible electronic devices and the like. For example, it can be evaluated by the 5% weight loss temperature of the polyimide film. The 5% weight loss temperature is preferably 515° C. or higher, more preferably 517° C. or higher, and further more preferably 520° C. or higher. When the 5% weight loss temperature is in the “preferred range”, it is considered as a material with clearly improved thermal decomposition resistance. If it is within the “further more preferable range”, it is recognized as a material with remarkably improved thermal decomposition resistance. Even if the 5% weight loss temperature is improved by only a 2 or 3° C., the process margin is improved, which is advantageous for stable production of flexible electronic devices.

In addition, when contamination by outgassing is a particular problem, it is also preferable that the thermal decomposition resistance of the polyimide film (or the polyimide that constitutes it) is evaluated using stricter criteria such as the 0.5% weight loss temperature of the polyimide film.

The 0.5% weight loss temperature is preferably 482° C. or higher, more preferably 484° C. or higher, and further more preferably 489° C. or higher.

The thermal decomposition resistance of a polyimide film (or the polyimide that constitutes it) may also be evaluated by the weight loss ratio when held at a constant high temperature for a certain period. For example, it can be evaluated by holding at an appropriate temperature selected from the range of 400° C. to 420° C. for an appropriate time selected from 2 to 6 hours under an inert atmosphere and determining the weight loss ratio.

The polyimide film of the present invention has an extremely low coefficient of linear thermal expansion. In one embodiment of the present invention, the coefficient of linear thermal expansion (CTE) of the polyimide film from 150° C. to 250° C., when measured on a 10 μm thick film, is preferably 20 ppm/K or less, more preferably less than 20 ppm, further more preferably 15 ppm/K or less, further more preferably 11 ppm/K or less, and most preferably 10 ppm/K or less.

In one embodiment of the present invention, the glass transition temperature (Tg) of the polyimide film (or the polyimide constituting it) is preferably 390° C. or higher, more preferably 400° C. or higher, further more preferably 410° C. or higher, and further more preferably 415° C. or higher, further more preferably 420° C. or higher, further more preferably 425° C. or higher, further more preferably 430° C. or higher, further more preferably 435° C. or higher, and most preferably 440° C. or higher.

In one embodiment of the present invention, when measured with a film having a thickness of 10 μm, the 400 nm light transmittance of the polyimide film is preferably 70% or higher, more preferably 73% or higher, more preferably 75% or higher, further more preferably 80% or higher. Further, when measured with a film having a thickness of 10 μm, the yellow index (YI) of the polyimide film is preferably 6.0 or less, more preferably 5.0 or less, further more preferably 4.0 or less, and further more preferably 3.2 or less, further more preferably 3.0 or less, and most preferably 2.7 or less. Generally, 0 or more is preferable.

In one embodiment of the present invention, when measured with a film having a thickness of 10 μm, the haze value of the polyimide film is preferably less than 1.0%, more preferably 0.8% or less, further more preferably 0.7% or less. For example, if the haze value exceeds 1%, it becomes unsuitable for optical applications because white turbidity is visually recognizable.

Here, the optical properties will be explained. 400 nm light transmission can be used as an index to estimate and evaluate the degree of yellowness and transparency of the film. For example, wholly aromatic polyimide films such as Upilex-S (Upilex is a registered trademark of Ube Industries) and Kapton (registered trademark) have generally yellowish brown color. This is because they absorb wavelengths of 380 nm to 500 nm (violet to blue light) in the visible light region. When aiming at a colorless and highly transparent polyimide film as in the present application, higher 400 nm light transmittance is more preferred.

Yellow index (YI) is calculated from a color system (for example, tristimulus values of X, Y, and Z) converted from the transmitted wavelength (transmittance). The ideal white color has a yellow index of 0, and a hue shift in the yellow direction is a positive value, and a hue shift in the blue direction is a negative value. Therefore, as a polyimide film, the yellow index closer to 0 is more preferred. Incidentally, since the yellow index is an index showing the relative relationship between the tristimulus values, for example, further if the 400 nm light transmittance is small, if the transmittance in other visible light regions is similarly small, the yellow index does not increase. It is not a value that indicates the transparency of the film.

Haze (cloudiness) is an index for evaluating the degree of “cloudiness or turbidity” of a film, and indicates the ratio of transmitted scattered light to total transmitted light transmitted through the film (transmitted scattered light/total transmitted light×100). A receiver fitted to the standard visual curve is used. The haze value of the film is preferably as small as possible. When the haze value exceeds 1%, the cloudiness is such degree that can be visually recognized as white turbidity.

In the present application, total light transmittance (or total light transmittance) represents the average transmittance of the entire visible light region (380 nm to 780 nm). On the other hand, in haze measurement, the transmittance (percentage) of light that includes both the parallel component and the diffuse component transmitted through the film (sample) is also called “total light transmittance” and may be confused. The haze measurement uses a D65 light source (average daylight) and uses a receiver fitted to the standard spectral luminosity curve V(λ) (equal to the color-matching function y(λ)), therefore, the region peaks around 555 nm is heavily weighted, and the transmittance near the wavelength of 400 nm hardly contributes to the “total light transmittance”. Therefore, it should be noted that the “total light transmittance” measured with a haze meter does not indicate the transmittance of the entire visible light region, unlike the total light transmittance (or total light transmittance) of the present application.

Furthermore, in one embodiment of the present invention, the elongation at break of the polyimide film is preferably 4% or more, more preferably 7% or more when measured with a film having a thickness of 10 μm.

In another preferred embodiment of the present invention, the breaking strength of the polyimide film is preferably 150 MPa or more, more preferably 170 MPa or more, further more preferably 180 MPa or more, further more preferably 200 MPa or more, and further more preferably 210 MPa or more. As the breaking strength, for example, a value obtained from a film having a thickness of about 5 to 100 μm can be used.

It is particularly preferred that the above desirable properties for the polyimide film are satisfied at the same time.

A polyimide film can be manufactured by a well-known method. A typical method is a method in which a polyimide precursor composition is flow-casted on a base material, and then heat-imidized on the base material to obtain a polyimide film. This method is described below in connection with the production of polyimide film/substrate laminates. Alternatively, a polyimide film can also be obtained by (i) producing a self-supporting film by flow-casting the polyimide precursor composition on the base material and drying it by heating, (ii) peeled off the self-supporting film from the base material, and (iii) thermally imidizing it while holding the film by, for example, a tenter keepint the both sides of the film in degass able state.

### <<Manufacturing of Polyimide Film/Substrate Laminate and Flexible Electronic Device>>

A polyimide film/substrate laminate can be produced using the polyimide precursor composition of the present invention. The polyimide film/substrate laminate is produced by (a) applying the polyimide precursor composition onto a substrate; (b) heat-treating the polyimide precursor on the substrate to form a laminate in which the polyimide film is laminated on the substrate (polyimide film/substrate laminate). A method of manufacturing a flexible electronic device, of the present invention comprises, using the polyimide film/substrate laminate produced above step (a) and step (b), further steps of (c) forming at least one layer selected from a conductor layer and a semiconductor layer on the polyimide film of the laminate; and (d) separating the substrate and the polyimide film.

First, in step (a), a polyimide precursor composition is cast on a substrate, imidized and desolvated by heat treatment to form a polyimide film, to obtain a laminate of the substrate and the polyimide film (polyimide film/substrate laminate).

As the substrate, a heat-resistant material is used. For example, a plate-like or a sheet-like substrate of, for example, ceramic materials (glass, alumina, and the like), metal materials (iron, stainless steel, copper, aluminum, and the like), semiconductor materials (silicon, compound semiconductors, and the like), or a film or sheet-like substrate of heat-resistant plastic materials (polyimide and the like) may be used. In general, a flat and smooth plate shape is preferable, and glass substrates of soda lime glass, borosilicate glass, alkali-free glass, sapphire glass, and the like; semiconductor (including compound semiconductors) substrates of silicon, GaAs, InP, GaN and the like; metal substrates of iron, stainless steel, copper, aluminum and the like are generally used.

A glass substrate is particularly preferable as the substrate. Glass substrates that are flat, smooth, and have a large area have been developed and are readily available. The thickness of the plate-like substrate such as a glass substrate is not limited, but from the viewpoint of ease of handling, it is, for example, 20 μm to 4 mm, preferably 100 μm to 2 mm. The size of the plate-like substrate is not particularly limited, but one side (long side in the case of a rectangle) is, for example, about 100 mm to 4000 mm, preferably about 200 mm to 3000 mm, more preferably about 300 mm to 2500 mm.

These substrates such as glass substrates may have an inorganic thin film (for example, a silicon oxide film) or a resin thin film formed on the surface thereof.

The method of casting the polyimide precursor composition onto the substrate is not particularly limited, and examples thereof include slit coating, die coating, blade coating, spray coating, inkjet coating, nozzle coating, spin coating, and screen printing method, bar coater method, electrodeposition method, and other conventionally known methods.

In step (b), the polyimide precursor composition is heat-treated on the substrate to convert it into a polyimide film to obtain a polyimide film/substrate laminate. The heat treatment conditions are not particularly limited. For example, it is preferred that after drying in a temperature range of 50° C. to 150° C., the film is processed such that the maximum heating temperature is, for example, 150° C. to 600° C., preferably 200° C. to 550° C., more preferably 250° C. to 500° C.

The thickness of the polyimide film is preferably 1 μm or more, more preferably 2 μm or more, and further more preferably 5 μm or more. If the thickness is less than 1 μm, the polyimide film cannot maintain sufficient mechanical strength, and when used as a flexible electronic device substrate, for example, it may not withstand stress and break. Also, the thickness of the polyimide film is preferably 100 μm or less, more preferably 50 μm or less, and further more preferably 20 μm or less. When the thickness of the polyimide film increases, it may become difficult to reduce the thickness of the flexible device. The thickness of the polyimide film is preferably 2 to 50 μm in order to make it thinner while maintaining sufficient resistance as a flexible device.

In the present invention, it is preferable that the polyimide film/substrate laminate has a small warp. Details of the measurement are described in Japanese Patent No. 6798633. In one embodiment, the residual stress is preferably less than 27 MPa when the properties of the polyimide film are evaluated in terms of residual stress between the polyimide film and the silicon substrate in the polyimide film/silicon substrate (wafer) laminate. Herein, the polyimide film is assumed to be placed at 23° C. in a dry state.

The polyimide film in the polyimide film/substrate laminate may have a second layer such as a resin film or an inorganic film on its surface. That is, after forming a polyimide film on a substrate, a second layer may be laminated to form a flexible electronic device substrate. It preferably has at least an inorganic film, and particularly preferably one that functions as a barrier layer against water vapor, oxygen (air), or the like. Examples of water vapor barrier layers include inorganic films containing inorganic materials selected from the group consisting of metal oxides, metal nitrides and metal oxynitrides such as silicon nitride (SiNₓ), silicon oxide (SiOₓ), silicon oxynitride (SiOₓN_{y}), aluminum oxide (Al₂O₃), titanium oxide (TiO₂), zirconium oxide (ZrO₂). Generally known methods for forming these thin films include physical vapor deposition methods such as vacuum vapor deposition, sputtering, and ion plating, and chemical vapor deposition (chemical vapor phase growth method) such as plasma CVD and catalytic chemical vapor deposition (Cat-CVD). This second layer can also be a multilayer structure.

When the second layer has a plurality of layers, it is possible to combine a resin film and an inorganic film, and examples thereof include those obtained by forming a three-layer structure of barrier layer/polyimide layer/barrier layer on the polyimide film in the polyimide film/substrate laminate.

In step (c), using the polyimide/substrate laminate obtained in step (b), on a polyimide film (including a second layer such as an inorganic film laminated on the surface of the polyimide film), at least one layer selected from a conductor layer and a semiconductor layer is formed. These layers may be formed directly on the polyimide film (including the lamination of the second layer) or may be formed on the surface of the other deposited (laminated) layers required for the device, namely, indirectly on the polyimide film.

For the conductor layer and/or the semiconductor layer, an appropriate conductor layer and (inorganic or organic) semiconductor layer are selected according to the elements and circuits required by the intended electronic device. When forming at least one of the conductor layer and the semiconductor layer in the step (c) of the present invention, it is also preferable to form at least one of the conductor layer and the semiconductor layer on the polyimide film on which the inorganic film has been formed.

The conductor layer and the semiconductor layer include both those formed on the entire surface of the polyimide film and those formed on a part of the polyimide film. In the present invention, step (d) may be performed immediately after step (c), or after forming at least one layer selected from a conductor layer and a semiconductor layer in step (c) and after further device structure(s) is formed after step (c), the step (d) may be performed.

When manufacturing a TFT liquid crystal display device as a flexible device, for example, a metal wiring, a TFT made of amorphous silicon or polysilicon, and a transparent pixel electrode are formed on a polyimide film on which an inorganic film is formed on the entire surface if necessary. A TFT includes, for example, a gate metal layer, a semiconductor layer such as an amorphous silicon film, a gate insulating layer, wiring connected to a pixel electrode, and the like. On top of this, a structure necessary for a liquid crystal display can also be formed by a known method. Also, a transparent electrode and a color filter may be formed on the polyimide film.

When manufacturing an organic EL display, for example, a transparent electrode, a light-emitting layer, a hole-transporting layer, an electron-transporting layer, and the like and a TFT as necessary are formed on a polyimide film on which an inorganic film is formed on the entire surface if necessary.

Since the polyimide film preferred in the present invention is excellent in various properties such as heat resistance and toughness, there are no particular restrictions on the method of forming the circuits, elements and other structures necessary for the device.

Next, in step (d), the substrate and the polyimide film are separated. The peeling method may be a mechanical peeling method of physically peeling by applying an external force, or a so-called laser peeling method of peeling by irradiating a laser beam from the substrate surface.

After peeling off the substrate, a device is completed by forming or incorporating a structure or parts necessary for the device into a (semi-) product having the polyimide film as a substrate.

As a different method for producing a flexible electronic device, after a polyimide film/substrate laminate by the above step (b) is produced and then the polyimide film is peeled off, a (semi-) product using a polyimide film as a substrate is produced by forming at least one layer selected from a conductor layer and a semiconductor layer, and necessary structures.

### EXAMPLES

The present invention will be further described below with reference to Examples and Comparative Examples. However, the present invention is not limited to the Examples as described below.

In each of the Examples as described below, the evaluations were conducted by the following methods.

### Evaluation of Polyimide Film

### [400 nm Light Transmittance, Total Light Transmittance]

The light transmittance at 400 nm of the polyimide film having a thickness of 10 μm was measured using a UV-visible spectrophotometer V-650DS (made by JASCO Corporation). The total light transmittance is the average of the transmittance from 380 nm to 780 nm.

### [Yellow Index (YI)]

YI of the polyimide film was measured according to the ASTEM E313 standard using an ultraviolet-visible spectrophotometer/V-650DS (manufactured by JASCO Corporation). The light source was D65 and the viewing angle was 2°.

### [Modulus of Elasticity, Elongation at Break, Strength at Break]

The polyimide film having a thickness of about 10 μm was cut to a dumbbell shape of IEC-540(S) standard to form a test piece, and the initial modulus of elasticity, the elongation at break, and the strength at break were measured at a distance between chucks of 30 mm and a tensile speed of 2 mm/min using a TENSILON made by Orientec Co., Ltd.

### [Coefficient of Linear Thermal Expansion (CTE), Glass Transition Temperature (Tg)]

The polyimide film was cut to a rectangle having a width of 4 mm, which was used as a test piece, and the test piece was heated to 500° C. at a distance between chucks of 15 mm, a load of 2 g and a temperature-increasing rate of 20° C./min using a TMA/SS6100 (made by SII Nanotechnology Inc.). The coefficient of linear thermal expansion from 100° C. to 250° C. was determined from the obtained TMA curve. In addition, the glass transition temperature (Tg) was determined from the inflection point.

### [5% Weight Loss Temperature, 0.5% Weight Loss Temperature]

The polyimide film having a thickness of about 10 μm was used as a test piece, and the test piece was heated from 25° C. to 600° C. at a temperature-increasing rate of 10° C./min in a flow of nitrogen using a thermogravimetric measuring apparatus (Q5000IR) made by TA Instruments Inc. The 5% weight loss temperature and 0.5% weight loss temperature were determined from the obtained weight curve taking the weight at 150° C. as 100%.

### [Haze]

The haze of a polyimide film having a film thickness of about 10 μm and a size of 5 cm square was measured according to the JIS K7136 standard using a turbidity meter/NDH2000 (manufactured by Nippon Denshoku Industries).

### [Polyimide Precursor Composition, Fluidity and Storage Stability of Polyimide Precursor Solution]

About 20 mL of the polyimide precursor composition was fed into a 50 mL sample bottle. Inside of the bottle was replaced with nitrogen, and sealed. It was stored at 23° C., and fluidity was confirmed after 10 days and 30 days.
o: When the closed container was tilted at 90° or more, the sample in which the solution moves was rated as o (good).
x: When the closed container was tilted at 90° or more, the sample in which the solution does not move was rated as x (bad).

### Raw Materials

The abbreviations, purities, etc. of the raw materials used in each of the Examples as described below are as follows.

### [Diamine Component]

DABAN: 4,4′-diaminobenzanilide
PPD: p-phenylenediamine
BAPB: 4,4′-bis(4-aminophenoxy)biphenyl
TFMB: 2,2′-bis(trifluoromethyl)benzidine
m-TD: m-tolysine
4,4-ODA: 4,4′-diaminodiphenyl ether

### [Tetracarboxylic Acid Component]

BNBDA: 2,2′-binorbornane-5,5′,6,6′-tetracarboxylic dianhydride
CpODA: norbornane-2-spiro-α-cyclopentanone-α′-spiro -2″-norbornane-5,5″,6,6″-tetracarboxylic dianhydride
PMDA-H: cyclohexanetetracarboxylic dianhydride

### [Imidazole Compound]

2-Pz: 2-phenylimidazole
1,2-DMz: 1,2-dimethylimidazole
z: imidazole
Bz: benzimidazole
2-Mz: 2-methylimidazole

### [Solvent]

NMP: N-methyl-2-pyrrolidone

Table 1-1 shows the structural formulas of the tetracarboxylic acid component and the diamine component, and Table 1-2 shows the structural formula of the imidazole compound.

TABLE 1-1

| Tetracarboxylic acid | |
|---|---|
| dianhydride | Diamine |
| 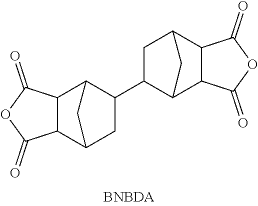 [SMILES: O=C1OC(=O)C2C3CC(CC3C3CC4CC3C3C(=O)OC(=O)C43)C12] | 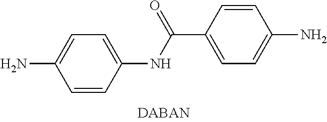 [SMILES: Nc1ccc(NC(=O)c2ccc(N)cc2)cc1] |
| 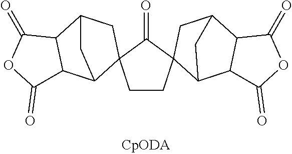 [SMILES: O=C1OC(=O)C2C1C1CC2C2(CCC3(CC4CC3C3C(=O)OC(=O)C43)C2=O)C1] | 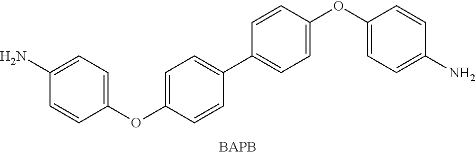 [SMILES: Nc1ccc(Oc2ccc(-c3ccc(Oc4ccc(N)cc4)cc3)cc2)cc1] |
| 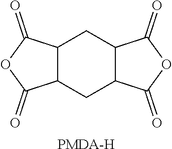 | 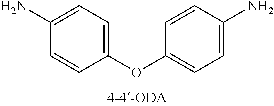 [SMILES: Nc1ccc(Oc2ccc(N)cc2)cc1] |
| | 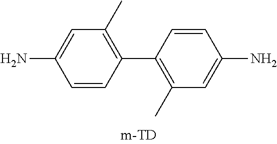 [SMILES: Cc1cc(N)ccc1-c1ccc(N)cc1C] |
| | 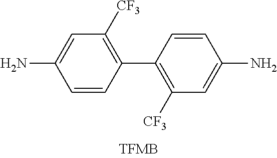 [SMILES: Nc1ccc(-c2ccc(N)cc2C(F)(F)F)c(C(F)(F)F)c1] |

TABLE 1-2
Imidazole compound

| | | | | |
|---|---|---|---|---|
| 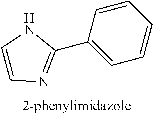 [SMILES: c1ccc(-c2ncc[nH]2)cc1] | 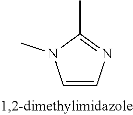 | 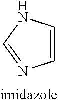 | 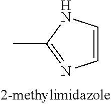 | 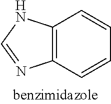 |

### Example 1

### [Preparation of Polyimide Precursor Composition]

Into a reaction vessel purged with nitrogen gas, 2.27 g (0.010 mol) of DABAN was charged and N-methyl-2-pyrrolidone was added was added in an amount of 32.11 g such that the total mass of the charged monomers (the sum of the diamine component and the carboxylic acid component) becomes 16% by mass, and the mixture was stirred at 50° C. for 1 hour. To this solution, 3.34 g (0.010 mol) of BNBDA was gradually added. After stirring at 70° C. for 4 hours, a uniform and viscous polyimide precursor solution was obtained.

2-Phenylimidazole as an imidazole compound was dissolved in four times the mass of N-methyl-2-pyrrolidone to obtain a uniform solution having a solid concentration of 20% by mass of 2-phenylimidazole. The imidazole compound solution and the polyimide precursor solution synthesized above are mixed so that the amount of the imidazole compound is 0.5 mol with respect to 1 mol of the repeating unit of the polyimide precursor, and the mixture was stirred at room temperature for 3 hours to obtain a homogeneous and viscous polyimide precursor composition.

### [Production of Polyimide Film]

As a glass substrate, a 6-inch Eagle-XG (registered trademark) (500 μm thick) manufactured by Corning was used. A polyimide precursor composition is applied onto a glass substrate by a spin coater, and under a nitrogen atmosphere (oxygen concentration of 200 ppm or less), the glass substrate is heated from room temperature to 440° C. to thermally imidize, thereby a polyimide film/substrate laminate was obtained. The laminate was immersed in water at 40° C. (eg. temperature range of 20° C. to 100° C.) to separate the polyimide film from the glass substrate, and after drying, the properties of the polyimide film were evaluated. The film thickness of the polyimide film is about 10 μm. Table 2 shows the evaluation results.

### Examples 2 to 26

A polyimide precursor composition was obtained in the same manner as in Example 1, except that the tetracarboxylic acid component, diamine component and imidazole compound were changed to the compounds and amounts (molar ratio) shown in Tables 2 to 4, and the amic acid concentration was adjusted as shown in the tables. Thereafter, a polyimide film was produced in the same manner as in Example 1, and the physical properties of the film were evaluated.

### Comparative Examples 1 to 16

Also in Comparative Examples, a polyimide precursor composition was obtained in the same manner as in Example 1, except that the tetracarboxylic acid component, diamine component and imidazole compound were changed to the compounds and amounts (molar ratio) shown in Tables 5 and 6, and the amic acid concentration was adjusted as shown in the tables. Thereafter, the physical properties of the film were evaluated in the same manner as in Example 1. A comparative example in which the additive column is blank indicates that no imidazole compound was added.

### Results of Physical Properties of Films of Examples and Comparative Examples

Comparative Examples 1, 2, 5 to 14 are precursor compositions to which no imidazole compound is added. The compositions of the corresponding examples to which imidazole was added had improved haze values, 400 nm light transmittance and coefficient of linear thermal expansion compared to these comparative examples.

Comparative Example 3 (CpODA/DABAN+imidazole compound) has the same composition as Example 1, etc., except that the tetracarboxylic acid component was changed to CpODA. The polyimide film obtained in Comparative Example 3 has excellent heat resistance in addition to optical properties such as transparency. However, the polyimide film obtained in the examples of the present invention has a 0.5% weight loss temperature and a 5% weight loss temperature higher than those of Comparative Example 3 while having optical properties equivalent to those of Comparative Example 3. Therefore, it was confirmed that the polyimide film obtained from the present invention has extremely excellent thermal decomposition resistance. In addition, since the polyimide film obtained from Comparative Example 16 has a haze value as small as 0.3%, it was shown that the composition of CpODA/DABAN does not have a problem of haze, regardless of the presence or absence of the addition of the imidazole compound (Comparative Examples 3 and 16). Therefore, it was confirmed that the problem of haze is unique problem to the composition based on BNBDA/DABAN.

Comparative Example 4 is a comparative example in which the amount of PMDA-H in the tetracarboxylic acid component was increased and the amount of BNBDA was reduced to 60% of the tetracarboxylic acid component in Example 16. A decrease in heat resistance is observed.

### [Storage Stability of Polyimide Precursor Composition]

The polyimide precursor compositions of Examples and Comparative Examples were tested for fluidity and storage stability. The polyimide precursor compositions of the Examples maintained fluidity both after 10 days and after 30 days, and thus they have excellent storage stability. On the other hand, as shown in Table 7, the polyimide precursor solution of Comparative Example, to which imidazole was not added, had poor storage stability due to decreased fluidity during storage. Also, as shown in Comparative Example 15, if the amount of the imidazole compound added is too large, the storage stability is lowered. Comparative Examples 3 and 16, which are polyimide precursor compositions using CpODA as a tetracarboxylic acid component, exhibited good storage stability even without adding an imidazole compound. Storage stability is therefore shown to be a unique problem when using BNBDA.

TABLE 2

| | | | | | | | | | Exam- | Exam- | Exam- |
|---|---|---|---|---|---|---|---|---|---|---|---|
| | | Example | Example | Example | Example | Example | Example | Example | ple | ple | ple |
| | | 18 | 1 | 19 | 20 | 21 | 22 | 23 | 24 | 25 | 26 |
| Acid dianhydride | BNBDA | 10 | 10 | 10 | 10 | 10 | 10 | 10 | 10 | 10 | 10 |
| (molar ratio) | CpODA | | | | | | | | | | |
| | PMDA-H | | | | | | | | | | |
| Diamine | DABAN | 10 | 10 | 10 | 10 | 10 | 10 | 10 | 10 | 10 | 10 |
| (molar ratio) | TFMB | | | | | | | | | | |
| | m-TD | | | | | | | | | | |
| | 4,4-ODA | | | | | | | | | | |
| | BAPB | | | | | | | | | | |
| Additive | 2-Pz | 2.5 | 5 | 10 | 20 | | | | | | 1 |
| (molar ratio) | 1,2-DMz | | | | | 2.5 | 5 | | | | |
| | z | | | | | | | 5 | | | |
| | Bz | | | | | | | | 5 | | |
| | 2-Mz | | | | | | | | | 1 | 5 |

| | | | | | | | | | | |
|---|---|---|---|---|---|---|---|---|---|---|
| Varnish | | | | | | | | | | |
| Amic acid concentration (wt %) | 16 | 16 | 16 | 15 | 16 | 16 | 16 | 16 | 16 | 16 |
| Polyimide film | | | | | | | | | | |
| Maximum heating temperature | 440 | 440 | 440 | 440 | 440 | 440 | 440 | 440 | 440 | 440 |
| at film formation (° C.) | | | | | | | | | | |
| Transmittance at 400 nm (%) | 81 | 80 | 82 | 83 | 82 | 83 | 80 | 79 | 78 | 79 |
| Total light transmittance (%) | 87 | 87 | 87 | 88 | 88 | 88 | 87 | 87 | 87 | 87 |
| YI | 2.7 | 3.0 | 2.2 | 2.4 | 3.1 | 3.0 | 3.4 | 3.7 | 3.9 | 3.1 |
| Haze (%) | 0.2 | 0.2 | 0.2 | 0.1 | 0.3 | 0.2 | 0.3 | 0.5 | 0.7 | 0.1 |
| Modulus of elasticity (Gpa) | 8.1 | 8.5 | 8.1 | 7.8 | 8.2 | 8.2 | 8.3 | 8.6 | 8.4 | 8.1 |
| Elongation at break (%) | 10 | 12 | 13 | 14 | 10 | 14 | 10 | 9 | 7 | 14 |
| Strength at break (MPa) | 281 | 295 | 297 | 280 | 256 | 289 | 250 | 263 | 220 | 268 |
| CTE (ppm/K) | 8 | 9 | 9 | 11 | 12 | 12 | 10 | 11 | 12 | 12 |
| (150-250° C.) | | | | | | | | | | |
| 0.5% weight loss temperature (° C.) | 495 | 500 | 495 | 495 | 495 | 492 | 493 | 493 | 494 | 498 |
| 5% weight loss temperature (° C.) | 526 | 528 | 526 | 525 | 526 | 524 | 525 | 527 | 524 | 527 |
| Tg (° C.) | 448 | 445 | 445 | 443 | 443 | 444 | 441 | 442 | 442 | 441 |

CTE: Coefficient of Linear Thermal Expansion

TABLE 3

| | | Example | Example | Example | Example | Example | Example | Example |
|---|---|---|---|---|---|---|---|---|
| | | 2 | 3 | 4 | 5 | 6 | 7 | 8 |
| Acid dianhydride | BNBDA | 10 | 10 | 10 | 10 | 10 | 10 | 10 |
| (molar ratio) | CpODA | | | | | | | |
| | PMDA-H | | | | | | | |
| Diamine | DABAN | 8 | 9 | 7 | 9 | 8 | 9 | 8 |
| (molar ratio) | TFMB | | | | | | | |
| | m-TD | | | | | | 1 | 2 |
| | 4,4-ODA | 2 | 1 | 3 | | | | |
| | BAPB | | | | 1 | 2 | | |
| Additive | 2-Pz | 1 | 1 | 1 | 1 | 1 | 1 | 1 |
| (molar ratio) | 1,2-DMz | | | | | | | |
| | z | | | | | | | |
| | Bz | | | | | | | |
| | 2-Mz | | | | | | | |

| | | | | | | | |
|---|---|---|---|---|---|---|---|
| Varnish | | | | | | | |
| Amic acid concentration (wt %) | 20 | 20 | 20 | 20 | 20 | 20 | 20 |
| Polyimide film | | | | | | | |
| Maximum heating temperature | 440 | 440 | 440 | 440 | 440 | 440 | 440 |
| at film formation (° C.) | | | | | | | |
| Transmittance at 400 nm (%) | 81 | 80 | 82 | 80 | 81 | 80 | 80 |
| Total light transmittance (%) | 87 | 86 | 87 | 87 | 87 | 87 | 87 |
| YI | 3.0 | 4.0 | 2.6 | 3.4 | 3.5 | 4.0 | 3.6 |
| Haze (%) | 0.4 | 0.4 | 0.5 | 0.3 | 0.4 | 0.3 | 0.7 |
| Modulus of elasticity (Gpa) | 7.1 | 7.8 | 6.4 | 7.4 | 6.6 | 8.9 | 8.6 |
| Elongation at break (%) | 13 | 11 | 12 | 5 | 14 | 7 | 12 |
| Strength at break (MPa) | 258 | 251 | 220 | 197 | 266 | 248 | 277 |
| CTE (ppm/K) | 13 | 11 | 15 | 11 | 14 | 12 | 8 |
| (150-250° C.) | | | | | | | |
| 0.5% weight loss temperature (° C.) | 497 | 498 | 495 | 494 | 492 | 495 | 491 |
| 5% weight loss temperature (° C.) | 521 | 524 | 517 | 522 | 518 | 519 | 515 |
| Tg (° C.) | 419 | 428 | 409 | 425 | 415 | 431 | 425 |

TABLE 4

| | | Example | Example | Example | Example | Example | Example | Example | Example | Example |
|---|---|---|---|---|---|---|---|---|---|---|
| | | 9 | 10 | 11 | 12 | 13 | 14 | 15 | 16 | 17 |
| Acid dianhydride | BNBDA | 10 | 10 | 10 | 10 | 10 | 10 | 10 | 8 | 7 |
| (molar ratio) | CpODA | | | | | | | | | |
| | PMDA-H | | | | | | | | 2 | 3 |
| Diamine | DABAN | 9 | 9 | 9 | 8 | 8 | 8 | 7 | 10 | 10 |
| (molar ratio) | TFMB | 1 | 1 | 1 | 2 | 2 | 2 | 3 | | |
| | m-TD | | | | | | | | | |
| | 4,4-ODA | | | | | | | | | |
| | BAPB | | | | | | | | | |
| Additive | 2-Pz | 1 | 5 | 10 | 1 | 5 | 10 | 1 | 5 | 5 |
| (molar ratio) | 1,2-DMz | | | | | | | | | |
| | z | | | | | | | | | |
| | Bz | | | | | | | | | |
| | 2-Mz | | | | | | | | | |

| | | | | | | | | | |
|---|---|---|---|---|---|---|---|---|---|
| Varnish | | | | | | | | | |
| Amic acid concentration (wt %) | 20 | 19 | 18 | 20 | 20 | 19 | 20 | 18 | 18 |
| Polyimide film | | | | | | | | | |
| Maximum heating temperature | 440 | 440 | 440 | 440 | 440 | 440 | 440 | 440 | 440 |
| at film formation (° C.) | | | | | | | | | |
| Transmittance at 400 nm (%) | 80 | 82 | 82 | 80 | 80 | 83 | 82 | 79 | 78 |
| Total light transmittance (%) | 87 | 87 | 88 | 87 | 86 | 88 | 88 | 87 | 87 |
| YI | 3.8 | 2.5 | 2.4 | 4.0 | 3.2 | 2.3 | 2.8 | 3.1 | 3.6 |
| Haze (%) | 0.8 | 0.2 | 0.2 | 0.7 | 0.6 | 0.3 | 0.4 | 0.3 | 0.2 |
| Modulus of elasticity (Gpa) | 7.9 | 8.2 | 8.0 | 7.4 | 7.6 | 7.9 | 7.5 | 6.8 | 6.7 |
| Elongation at break (%) | 5 | 9 | 12 | 4 | 7 | 11 | 10 | 15 | 21 |
| Strength at break (MPa) | 198 | 252 | 276 | 180 | 216 | 281 | 254 | 293 | 300 |
| CTE (ppm/K) | 9 | 8 | 8 | 9 | 9 | 9 | 8 | 10 | 12 |
| (150-250° C.) | | | | | | | | | |
| 0.5% weight loss temperature (° C.) | 490 | 495 | 494 | 489 | 485 | 484 | 488 | 492 | 485 |
| 5% weight loss temperature (° C.) | 521 | 522 | 517 | 520 | 517 | 515 | 517 | 519 | 515 |
| Tg (° C.) | 425 | 425 | 426 | 419 | 420 | 420 | 412 | 441 | 426 |

TABLE 5

| | | Comp-Ex | Comp-Ex | Comp-Ex | Comp-Ex | Comp-Ex | Comp-Ex | Comp-Ex | Comp-Ex |
|---|---|---|---|---|---|---|---|---|---|
| | | 1 | 2 | 5 | 6 | 7 | 8 | 9 | 10 |
| Acid dianhydride | BNBDA | 10 | 10 | 10 | 10 | 10 | 10 | 10 | 10 |
| (molar ratio) | CpODA | | | | | | | | |
| | PMDA-H | | | | | | | | |
| Diamine | DABAN | 10 | 8 | 9 | 7 | 9 | 8 | 9 | 8 |
| (molar ratio) | TFMB | | | | | | | | |
| | m-TD | | | | | | | 1 | 2 |
| | 4,4-ODA | | 2 | 1 | 3 | | | | |
| | BAPB | | | | | 1 | 2 | | |
| Additive | 2-Pz | | | | | | | | |
| (molar ratio) | 1,2-DMz | | | | | | | | |
| | z | | | | | | | | |
| | Bz | | | | | | | | |
| | 2-Mz | | | | | | | | |

| | | | | | | | | |
|---|---|---|---|---|---|---|---|---|
| Varnish | | | | | | | | |
| Amic acid concentration (wt %) | 16 | 20 | 20 | 20 | 20 | 20 | 20 | 20 |
| Polyimide film | | | | | | | | |
| Maximum heating temperature | 440 | 440 | 440 | 440 | 440 | 440 | 440 | 440 |
| at film formation (° C.) | | | | | | | | |
| Transmittance at 400 nm (%) | 72 | 74 | 71 | 76 | 72 | 73 | 70 | 75 |
| Total light transmittance (%) | 84 | 85 | 84 | 86 | 85 | 85 | 84 | 86 |
| YI | 5.5 | 5.8 | 6.6 | 5.0 | 6.2 | 6.1 | 7.3 | 5.9 |
| Haze (%) | 1.1 | 1.1 | 1.4 | 1.2 | 2.3 | 1.2 | 1.4 | 1.1 |
| Modulus of elasticity (Gpa) | 7 | 5.3 | 6.3 | 4.5 | 6 | 5 | 6.7 | 6.3 |
| Elongation at break (%) | 3 | 7 | 5 | 18 | 5 | 15 | 4 | 7 |
| Strength at break (MPa) | 78 | 147 | 171 | 169 | 159 | 175 | 161 | 173 |
| CTE (ppm/K) | 10 | 30 | 25 | 34 | 24 | 35 | 21 | 30 |
| (150-250° C.) | | | | | | | | |
| 0.5% weight loss temperature (° C.) | 485 | 480 | 494 | 488 | 489 | 487 | 490 | 486 |
| 5% weight loss temperature (° C.) | 526 | 519 | 525 | 517 | 521 | 516 | 517 | 515 |
| Tg (° C.) | 445 | 421 | 428 | 435 | 426 | 428 | 430 | 453 |

Comp-Ex: Comparative Example

TABLE 6

| | | Comp-Ex | Comp-Ex | Comp-Ex | Comp-Ex | Comp-Ex | Comp-Ex | Comp-Ex | Comp-Ex |
|---|---|---|---|---|---|---|---|---|---|
| | | 11 | 12 | 13 | 14 | 4 | 15 | 3 | 16 |
| Acid dianhydride | BNBDA | 10 | 10 | 8 | 7 | 6 | 10 | | |
| (molar ratio) | CpODA | | | | | | | 10 | 10 |
| | PMDA-H | | | 2 | 3 | 4 | | | |
| Diamine | DABAN | 9 | 7 | 10 | 10 | 10 | 10 | 10 | 10 |
| (molar ratio) | TFMB | 1 | 3 | | | | | | |
| | m-TD | | | | | | | | |
| | 4,4-ODA | | | | | | | | |
| | BAPB | | | | | | | | |
| Additive | 2-Pz | | | | | 5 | 30 | 1 | |
| (molar ratio) | 1,2-DMz | | | | | | | | |
| | z | | | | | | | | |
| | Bz | | | | | | | | |
| | 2-Mz | | | | | | | | |

| | | | | | | | | |
|---|---|---|---|---|---|---|---|---|
| Varnish | | | | | | | | |
| Amic acid concentration (wt %) | 20 | 20 | 19 | 19 | 23 | 15 | 16 | 16 |
| Polyimide film | | | | | | | | |
| Maximum heating temperature | 440 | 440 | 440 | 440 | 440 | — | 420 | 420 |
| at film formation (° C.) | | | | | | | | |
| Transmittance at 400 nm (%) | 74 | 68 | 70 | 75 | 74 | — | 81 | 77 |
| Total light transmittance (%) | 86 | 85 | 85 | 86 | 86 | — | 88 | 87 |
| YI | 5.8 | 8.9 | 6.1 | 4.7 | 4.8 | — | 2.6 | 5.3 |
| Haze (%) | 1.1 | 1.2 | 1.1 | 1.1 | 0.3 | — | 0.2 | 0.3 |
| Modulus of elasticity (Gpa) | 6.5 | 4.8 | 6.1 | 5.4 | 6.3 | — | 6.5 | 6.7 |
| Elongation at break (%) | 7 | 5 | 10 | 15 | 23 | — | 17 | 7 |
| Strength at break (MPa) | 200 | 124 | 199 | 203 | 287 | — | 247 | 2195 |
| CTE (ppm/K) | 16 | 37 | 29 | 30 | 16 | — | 12 | 12 |
| (150-250° C.) | | | | | | | | |
| 0.5% weight loss temperature (° C.) | 485 | 479 | 480 | 480 | 477 | — | 481 | 482 |
| 5% weight loss temperature (° C.) | 520 | 510 | 518 | 517 | 509 | — | 513 | 513 |
| Tg (° C.) | 425 | 434 | 439 | 430 | 416 | — | 415 | 415 |

Comp-Ex: Comparative Example

TABLE 7

| | | Comp-Ex | Comp-Ex | Comp-Ex | Comp-Ex | Comp-Ex | Comp-Ex |
|---|---|---|---|---|---|---|---|
| | | 1 | 5 | 11 | 15 | 3 | 16 |
| Acid dianhydride | BNBDA | 10 | 10 | 10 | 10 | | |
| (molar ratio) | CpODA | | | | | 10 | 10 |
| | PMDA-H | | | | | | |
| Diamine | DABAN | 10 | 9 | 9 | 10 | 10 | 10 |
| (molar ratio) | TFMB | | | 1 | | | |
| | m-TD | | | | | | |
| | 4,4-ODA | | 1 | | | | |
| | BAPB | | | | | | |
| Additive | 2-Pz | | | | 30 | 1 | |
| (molar ratio) | 1,2-DMz | | | | | | |
| | z | | | | | | |
| | Bz | | | | | | |
| | 2-Mz | | | | | | |

| | | | | | | |
|---|---|---|---|---|---|---|
| Varnish | | | | | | |
| Amic acid concentration (wt %) | 16 | 20 | 20 | 15 | 16 | 16 |
| fluidity after 10 days | x | x | x | ∘ | ∘ | ∘ |
| fluidity after 30 days | x | x | x | x | ∘ | ∘ |

Comp-Ex: Comparative Example

### INDUSTRIAL APPLICABILITY

The present invention is suitably applied to the manufacture of flexible electronic devices, for example, display devices such as liquid crystal displays, organic EL displays and electronic papers, and light receiving devices such as solar cells and CMOS.

1. A polyimide precursor composition comprising:
a polyimide precursor having repeating units represented by the following general formula (I),
at least one imidazole compound in an amount more than 0.01 mol and 2 mol or less based on one mol of the repeating units of the polyimide precursor, and
a solvent; 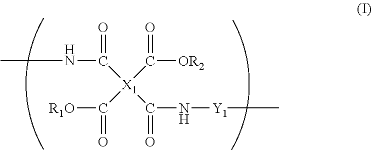
wherein in general formula I, X₁ is a tetravalent aliphatic group or aromatic group, Y₁ is a divalent aliphatic group or aromatic group, R₁ and R₂ are each independently a hydrogen atom, an alkyl group having 1 to 6 carbon atoms or an alkylsilyl group having 3 to 9 carbon atoms, wherein 70 mol % or more of X₁ is a structure represented by formula (1-1): 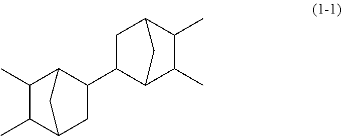
and 70 mol % or more of Y₁ is a structure represented by formula (D-1) and/or (D-2):

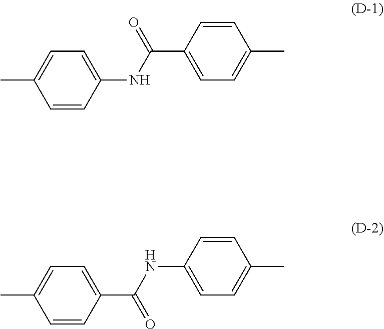

2. The polyimide precursor composition according to claim 1, wherein the imidazole compound is at least one selected from the group consisting of 1,2-dimethylimidazole, 1-methylimidazole, 2-methylimidazole, 2-phenylimidazole, imidazole and benzimidazole.

3. The polyimide precursor composition according to claim 1, wherein 90 mol % or more of X₁ has a structure represented by the formula (1-1).

4. The polyimide precursor composition according to claim 1, wherein a polyimide film obtained from the polyimide precursor composition has a 5% weight loss temperature of 515° C. or higher.

5. The polyimide precursor composition according to claim 1, wherein a polyimide film obtained from the polyimide precursor composition has a coefficient of linear thermal expansion of 20 ppm/K or less.

6. The polyimide precursor composition according to claim 1, wherein a polyimide film having a thickness of 10 μm obtained from the polyimide precursor composition has a haze value of less than 1.0%.

7. The polyimide precursor composition according to claim 1, which maintains fluidity when stored at 23° C. for 10 days in a sealed state.

8. A polyimide film obtained from the polyimide precursor composition according to claim 1.

9. A polyimide film/substrate laminate comprising:
a polyimide film obtained from the polyimide precursor composition according to claim 1, and
a substrate.

10. The laminate according to claim 9, wherein the substrate is a glass substrate.

11. A method of producing a polyimide film/substrate laminate comprising:
(a) applying the polyimide precursor composition according to claim 1 onto a substrate; and
(b) heat-treating the polyimide precursor on the substrate to laminate a polyimide film on the substrate.

12. The method according to claim 11, wherein the substrate is a glass substrate.

13. A method of manufacturing a flexible electronic device, comprising:
(a) applying the polyimide precursor composition according to claim 1 onto a substrate;
(b) heat-treating the polyimide precursor on the substrate;
(c) forming at least one layer selected from a conductor layer and a semiconductor layer on the polyimide film of the laminate; and
(d) separating the substrate and the polyimide film.

14. The method according to claim 13, wherein the substrate is a glass substrate.
